(19) United States
(12) Patent Application Publication
(10) Pub. No.: US 2024/0357904 A1
(43) Pub. Date: Oct. 24, 2024

(54) DISPLAY DEVICE AND ELECTRONIC APPLIANCE

(71) Applicant: SEMICONDUCTOR ENERGY LABORATORY CO., LTD., Atsugi-shi (JP)

(72) Inventor: Yuki HAYASHI, Atsugi (JP)

(21) Appl. No.: 18/632,440

(22) Filed: Apr. 11, 2024

(30) Foreign Application Priority Data
Apr. 21, 2023 (JP) 2023-070064

(51) Int. Cl. H10K 59/80; H10K 59/35

(52) U.S. Cl. CPC H10K 59/873; H10K 59/35; H10K 59/8791

(57) ABSTRACT

A display device in which a color conversion layer using quantum dots hardly deteriorates is provided. The display device includes a substrate, an insulating layer, a color conversion layer, a first inorganic film, and a second inorganic film; the insulating layer is positioned over the substrate and has an opening; the color conversion layer includes a portion positioned in the opening; the first inorganic film includes a portion positioned between the insulating layer and the color conversion layer in the opening and a portion positioned between the substrate and the color conversion layer in the opening; and the second inorganic film includes a portion positioned over the color conversion layer.

### BACKGROUND OF THE INVENTION

### 1. Field of the Invention

One embodiment of the present invention relates to an organic semiconductor device, a light-emitting device, a light-receiving device, a light-emitting apparatus, a light-receiving apparatus, a display device, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Displays using quantum dots (QDs) for a color conversion layer have started to spread. The quantum dot refers to a nanoparticle of a semiconductor, whose diameter is as small as several nanometers. With the quantum size effect, the band gap can be adjusted on the basis of the size of the particles; thus, incident light can be converted into light with a different wavelength depending on the size of the particles. Specifically, incident light can be converted into light with a shorter wavelength with a reduction in the size of the particle, and can be converted into light with a longer wavelength with an increase in the size of the particle. A display using quantum dots for the color conversion layer can perform full-color display by utilizing that property, that is, by changing the size of the particle on the subpixel basis so that light with the same wavelength can be converted into light of different colors for different subpixels.

However, the quantum dot has disadvantages such as low durability and need for using cadmium with high toxicity in order to increase efficiency. For example, Patent Document 1 discloses that quantum dots might deteriorate due to impurities such as oxygen.

### REFERENCE

[Patent Document 1] Japanese Patent No. 6159302

### SUMMARY OF THE INVENTION

In a light-emitting apparatus in which quantum dots are used for a color conversion layer, when the quantum dots and the color conversion layer deteriorate, problems such as a reduction in display quality of the display device arise.

In view of the above, an object of one embodiment of the present invention is to prevent entry of oxygen into the color conversion layer. Another object of one embodiment of the present invention is to provide a display device in which a color conversion layer hardly deteriorate. Another object of one embodiment of the present invention is to provide a display device whose color conversion layer can be easily formed in a manufacturing process. Another object of the display device of one embodiment of the present invention is to improve the display quality of a display device. Another object of one embodiment of the present invention is to provide a novel display device.

Note that the description of these objects does not preclude the existence of other objects. One embodiment of the present invention does not need to achieve all of these objects. Other objects will be apparent from and can be derived from the description of the specification, the drawings, the claims, and the like.

One embodiment of the present invention is a display device including a substrate, an insulating layer, a color conversion layer, a first inorganic film, and a second inorganic film; the insulating layer is positioned over the substrate and has an opening; the color conversion layer includes a portion positioned in the opening; the first inorganic film includes a portion positioned between the insulating layer and the color conversion layer in the opening and a portion positioned between the substrate and the color conversion layer in the opening; and the second inorganic film includes a portion positioned over the color conversion layer.

Another embodiment of the present invention is a display device including a substrate, an insulating layer, a color conversion layer, a first inorganic film, and a second inorganic film; the insulating layer is positioned over the substrate and has an opening; the color conversion layer includes a portion positioned in the opening; the first inorganic film includes a portion positioned between the insulating layer and the color conversion layer in the opening, a portion positioned between the substrate and the color conversion layer in the opening, and a portion positioned over the insulating layer; and the second inorganic film includes a portion positioned over the color conversion layer and a portion positioned over the first inorganic film over the insulating layer.

Another embodiment of the present invention is the display device which has the above-described structure and in which the first inorganic film includes a portion in contact with the second inorganic film.

Another embodiment of the present invention is a display device including a substrate, an insulating layer, a color conversion layer, a first inorganic film, a second inorganic film, and a third inorganic film; the insulating layer is positioned over the substrate and has an opening; the color conversion layer includes a portion positioned in the opening; the first inorganic film includes a portion positioned between the insulating layer and the color conversion layer in the opening, a portion positioned between the substrate and the color conversion layer in the opening, and a portion positioned over the insulating layer; the second inorganic film includes a portion positioned over the color conversion layer and a portion positioned over the first inorganic film over the insulating layer; and the third inorganic film includes a portion positioned between the substrate and the insulating layer and a portion positioned between the substrate and the first inorganic film.

Another embodiment of the present invention is the display device which has the above-described structure and in which the first inorganic film includes a portion in contact with the second inorganic film and the third inorganic film.

Another embodiment of the present invention is the display device which has any of the above-described structures and in which a height from a top surface of the substrate to a top surface of the insulating layer is higher than a height from the top surface of the substrate to a top surface of the color conversion layer.

Another embodiment of the present invention is the display device which has any of the above-described structures and which further includes a coloring layer, and the coloring layer includes a portion positioned between the substrate and the insulating layer and a portion positioned between the substrate and the first inorganic film.

Another embodiment of the present invention is the display device which has any of the above-described structures and which further includes a light-emitting device, and the light-emitting device overlaps with the color conversion layer.

Another embodiment of the present invention is an electronic appliance including any of the display devices with the above structures, and a sensing portion, an input portion, or a communication portion.

One embodiment of the present invention can prevent entry of oxygen into a color conversion layer. Another embodiment of the present invention can provide a display device in which a color conversion layer hardly deteriorates. Another embodiment of the present invention can provide a display device whose color conversion layer can be easily formed in a manufacturing process. Another embodiment of the present invention can provide a novel display device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view illustrating a structure of a display device of an embodiment and FIG. 1B is a cross-sectional view illustrating the structure of the display device of the embodiment;

FIGS. 2A and 2B are cross-sectional views illustrating structures of a display device of an embodiment;

FIGS. 3A to 3C are cross-sectional views illustrating structures of a display device of an embodiment;

FIGS. 4A to 4D are cross-sectional views illustrating structures of a display device of an embodiment;

FIGS. 5A to 5C are cross-sectional views illustrating structures of a display device of an embodiment;

FIGS. 6A and 6B are cross-sectional views illustrating structures of a display device of an embodiment;

FIGS. 7A to 7D are cross-sectional views illustrating a method for manufacturing a display device;

FIGS. 8A and 8B are cross-sectional views illustrating a method for manufacturing a display device;

FIGS. 9A to 9G are diagrams illustrating examples of pixels;

FIGS. 10A to 10I are diagrams illustrating examples of a pixel;

FIGS. 11A and 11B are perspective views illustrating an example of a display device;

FIG. 12 is a cross-sectional view illustrating an example of a display device;

FIGS. 13A to 13F are diagrams illustrating structure examples of a light-emitting device;

FIGS. 14A to 14D are diagrams illustrating structure examples of a light-emitting device;

FIG. 15 is a diagram illustrating light-emitting devices;

FIGS. 16A to 16D are diagrams illustrating examples of electronic appliances;

FIGS. 17A to 17F are diagrams illustrating examples of electronic appliances; and

FIGS. 18A to 18G are diagrams illustrating examples of electronic appliances.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

Note that in this specification and the like, the positional relation between components is described using the term “over” or “below” in some cases; however, the present invention should not be interpreted as being limited to the description. For example, in the case where the light extraction direction is described as “upward”, a layer formed later in a deposition order is described as a layer being positioned “over” the layer formed previously in some cases. In addition, without limitation to this, the term “over” or “below” is sometimes used to correspond to the vertical relation in the drawings.

### Embodiment 1

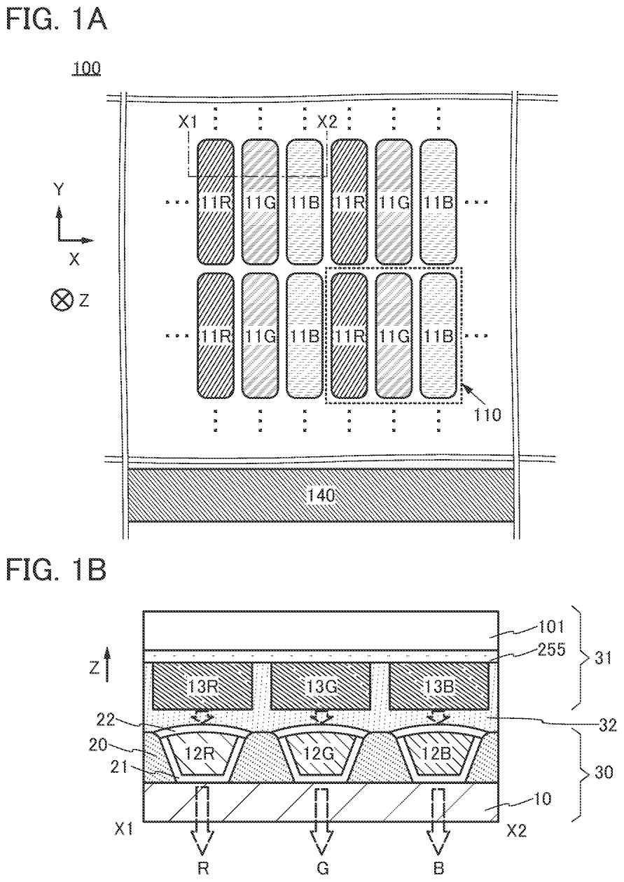

In this embodiment, a display device of one embodiment of the present invention will be described with reference to FIGS. 1A and 1B, FIGS. 2A and 2B, FIGS. 3A to 3C, FIGS. 4A to 4D, FIGS. 5A to 5C, and FIGS. 6A and 6B.

The display device of one embodiment of the present invention includes a plurality of light-emitting devices containing the same light-emitting material and a color conversion layer that overlaps with at least some of the light-emitting devices. By changing the presence or absence of the color conversion layer and the kind of the color conversion layer depending on subpixels, full-color display can be performed in the display device.

FIG. 1A is a top view of a display device 100. The display device 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and six columns, which form pixels 110 in two rows and two columns. The connection portion 140 can also be referred to as a cathode contact portion.

The top surface shape of the subpixel illustrated in FIG. 1A corresponds to the top surface shape of a light-emitting region. In this specification and the like, a top surface shape refers to a shape in a plan view, i.e., a shape seen from above.

Note that the top surface shape of the subpixel is not limited to the shape illustrated in FIG. 1A. Examples of the top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in FIG. 1A, and the components of the circuit may be placed outside the range of the subpixels. That is, some or all of the transistors included in a subpixel 11R in FIG. 1A may be positioned outside the range of the subpixel 11R. The transistors included in the subpixel 11R may be positioned within the range of the subpixel 11R, a subpixel 11G, or a subpixel 11B in FIG. 1A, or may be placed in a plurality of these ranges.

Although the subpixels 11R, 11G, and 11B have the same or substantially the same aperture ratio (also referred to as size or size of a light-emitting region) in FIG. 1A, one embodiment of the present invention is not limited thereto. Note that the aperture ratio of each of the subpixels 11R, 11G, and 11B can be determined as appropriate. The subpixels 11R, 11G, and 11B may have different aperture ratios, or two or more of the subpixels 11R, 11G, and 11B may have the same or substantially the same aperture ratio.

The pixel 110 illustrated in FIG. 1A employs stripe arrangement. The pixel 110 illustrated in FIG. 1A includes three subpixels of the subpixels 11R, 11G, and 11B. The subpixels 11R, 11G, and 11B emit light of different colors. The subpixels 11R, 11G, and 11B can be of three colors of red (R), green (G), and blue (B) or three colors of yellow (Y), cyan (C), and magenta (M), for example. The number of types of subpixels is not limited to three, and four or more types of subpixels may be used. The four types of subpixels can emit light of four colors of R, G, B, and white (W), four colors of R, G, B, and Y, or four types of R, G, B, and infrared (IR) light, for example.

In this specification and the like, the row direction, the column direction, and the depth direction are sometimes referred to as the X direction, the Y direction, and the Z direction, respectively. FIG. 1A illustrates an example where subpixels of different colors are arranged in the X direction and subpixels of the same color are arranged in the Y direction.

FIG. 1B is a cross-sectional view along the dashed-dotted line X1-X2 in FIG. 1A. Note that in the cross-sectional view in FIG. 1B, a top surface of the display device 100 is illustrated as facing downward.

The subpixel 11R includes a light-emitting device 13R and a color conversion layer 12R overlapping with the light-emitting device 13R. The color conversion layer 12R can convert light emitted from the light-emitting device 13R into red light. Thus, light emitted from the light-emitting device 13R is extracted as red light to the outside of the display device 100 through the color conversion layer 12R.

The subpixel 11G includes a light-emitting device 13G and a color conversion layer 12G overlapping with the light-emitting device 13G. The color conversion layer 12G can convert light emitted from the light-emitting device 13G into green light. Thus, light emitted from the light-emitting device 13G is extracted as green light to the outside of the display device 100 through the color conversion layer 12G.

The subpixel 11B includes a light-emitting device 13B and a color conversion layer 12B overlapping with the light-emitting device 13B. The color conversion layer 12B can convert light emitted from the light-emitting device 13B into blue light. Thus, light emitted from the light-emitting device 13B is extracted as blue light to the outside of the display device 100 through the color conversion layer 12B.

Here, an example of blue light is light having a peak wavelength in the emission spectrum of greater than or equal to 400 nm and less than 480 nm. An example of green light is light having a peak wavelength in the emission spectrum of greater than or equal to 480 nm and less than 580 nm. An example of red light is light having a peak wavelength in the emission spectrum of greater than or equal to 580 nm and less than or equal to 700 nm.

As the color conversion layer, one or both of a phosphor and a quantum dot is preferably used. In particular, a quantum dot has an emission spectrum with a narrow peak, so that emission with high color purity can be obtained. Thus, the display quality of the display device can be improved.

There is no limitation on a material of quantum dots, and examples include a Group 14 element, a Group 15 element, a Group 16 element, a compound of a plurality of Group 14 elements, a compound of an element belonging to any of Groups 4 to 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and a combinations thereof. What is called an alloyed quantum dot, whose composition is represented by a given ratio, may be used.

Examples of the quantum dot include a core quantum dot, a core-shell quantum dot, and a core-multishell quantum dot. Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It is also possible to reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the size is decreased; thus, the emission wavelengths of the quantum dots can be adjusted over a wavelength range in the spectrum of an ultraviolet region, a visible light region, and an infrared region by changing the size of the quantum dots. The range of size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light can be obtained with high color purity. The shape of quantum dots is not limited to a particular shape and may be a spherical shape, a rod shape, a circular shape, or the like. A quantum rod, which is a rod-shaped quantum dot, has a function of emitting directional light.

The color conversion layer can be formed by a droplet discharge method (e.g., an inkjet method), a coating method, an imprinting method, a variety of printing methods (screen printing or offset printing), or the like. A color conversion film such as a quantum dot film may also be used.

For processing a film to be the color conversion layer, a photolithography method is preferably employed. Examples of the photolithography method include a method in which a resist mask is formed over a thin film to be processed, the thin film is processed by etching or the like, and the resist mask is removed, and a method in which a photosensitive thin film is formed, and the photosensitive thin film is exposed to light and developed to be processed into a desired shape. For example, a thin film is formed using a material in which a quantum dot is mixed with a photoresist, and the thin film is processed by a photolithography method, whereby an island-shaped color conversion layer can be formed.

In the display device of one embodiment of the present invention, it is preferable that an insulating layer having an opening be provided over a substrate and a color conversion layer be provided in the opening. The insulating layer can be formed using an organic resin film such as an acrylic resin, a polyamide resin, or an epoxy resin; an inorganic insulating film; or organic polysiloxane. It is particularly preferable that the insulating layer be formed using a photosensitive resin material so that a sidewall of an opening has an inclined surface with continuous curvature. With the insulating layer, the color conversion layers of different colors can be separated from each other; thus, color mixture can be prevented. Accordingly, a display device having high display quality can be provided. Note that the insulating layer has a function of separating the color conversion layers of different colors, and thus is also referred to as a partition or a bank.

However, quantum dots are likely to deteriorate due to entry of impurities such as oxygen. In this case, the emission intensity of the pixels is decreased and the display quality of the display device is reduced; thus, in a display device using quantum dots for the color conversion layer, it is necessary to prevent entry of impurities such as oxygen from the periphery of the color conversion layer to inhibit the deterioration of the quantum dots.

In view of this, an inorganic film surrounding the color conversion layer is provided in the display device of one embodiment of the present invention. This can prevent entry of impurities such as oxygen into the color conversion layer, so that a display device with high display quality can be provided.

As illustrated in FIG. 1B, the display device 100 has a structure where a unit 30 including a substrate 10, a partition 20, the color conversion layers 12R, 12G, and 12B, a first inorganic film 21, and a second inorganic film 22 and a unit 31 including a layer 101 including transistors, an insulating layer 255, and the light-emitting devices 13R, 13G, and 13B are bonded to each other with a resin layer 32. Note that arrows indicated by dashed lines in FIG. 1B represent light emission directions.

In the unit 30, the partition 20 is an insulating layer positioned over the substrate 10 and includes an opening. The color conversion layers 12R, 12G, and 12B each include a portion positioned in the opening of the partition 20.

The first inorganic film 21 includes a portion between a side surface of the partition 20 and a side surface of any of the color conversion layers 12R, 12G, and 12B and a portion between the substrate 10 and any of the color conversion layers 12R, 12G, and 12B in the opening of the partition 20.

The second inorganic film 22 includes a portion over the color conversion layers 12R, 12G, and 12B.

That is, the color conversion layers 12R, 12G, and 12B are each surrounded by the first inorganic film 21 and the second inorganic film 22. In each subpixel, each of the color conversion layers 12R, 12G, and 12B can be regarded as being positioned between the first inorganic film 21 and the second inorganic film 22. With the first inorganic film 21 and the second inorganic film 22 in this manner, entry of impurities such as oxygen into the color conversion layers 12R, 12G, and 12B can be prevented; thus, deterioration of the color conversion layers 12R, 12G, and 12B due to impurities such as oxygen can be prevented. Therefore, a highly reliable display device can be obtained.

The first inorganic film 21 and the second inorganic film 22 are preferably in contact with the partition 20. This can prevent diffusion of the constituent elements of the partition 20 from the partition 20, so that the effect of inhibiting deterioration of the color conversion layers 12R, 12G, and 12B can be further increased by the first inorganic film 21 and the second inorganic film 22. Therefore, a higher reliable display device can be obtained.

An inorganic insulating film is suitable as the first inorganic film 21 and the second inorganic film 22. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used. In particular, a metal nitride film such as a film of silicon nitride or aluminum nitride is preferably used because oxygen is not contained in the material itself, so that entry of oxygen into the color conversion layer can be effectively prevented.

To inhibit transmission of oxygen or the like, the thicknesses of the first inorganic film 21, the second inorganic film 22, and a third inorganic film 23 are preferably greater than or equal to 10 nm, further preferably greater than or equal to 50 nm. Meanwhile, to inhibit a decrease in transmittance of light of the light-emitting device, the thicknesses of the first inorganic film 21, the second inorganic film 22, and the third inorganic film 23 are preferably less than or equal to 1000 nm, further preferably less than or equal to 500 nm.

For the substrate 10, glass, quartz, ceramic, sapphire, a resin, a metal, an alloy, a semiconductor, or the like can be used. The substrate on the side from which light from the light-emitting device is extracted is formed using a material which transmits the light. When a flexible material is used for the substrate 10, the flexibility of the display device can be increased. Furthermore, a polarizing plate or the like may be used as the substrate 10. As described above, a variety of members can be used for the substrate.

For the substrate 10, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 10.

In the case where a circularly polarizing plate overlaps with the display device, a highly optically isotropic substrate is preferably used as the substrate 10. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film used as the substrate 10 absorbs water, the shape of the display device might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the resin layer 32, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin may be used. An adhesive sheet or the like may be used.

In the unit 31, the insulating layer 255 is over the layer 101 including transistors, and the light-emitting devices 13R, 13G, and 13B are over the insulating layer 255. Note that “over” in this case is based on the vertical relation assuming that the layer 101 including transistors is on the lower side and the light-emitting devices 13R, 13G, and 13B are on the upper side. In other words, in the unit 31, the insulating layer 255 is in contact with the layer 101 including transistors, and the light-emitting devices 13R, 13G, and 13B are in contact with the insulating layer 255.

The display device of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces. In this embodiment, a top-emission display device is described as an example.

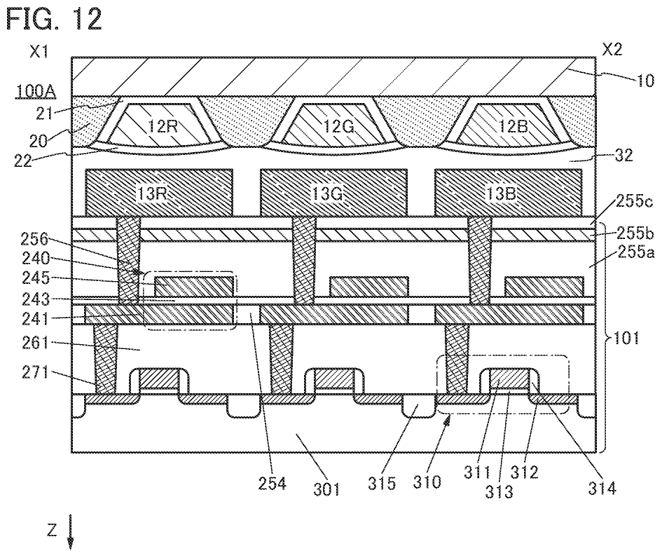

The layer 101 including transistors can employ a stacked-layer structure in which a plurality of transistors are provided over a substrate and an insulating layer is provided to cover these transistors, for example. The insulating layer over the transistors may have a single-layer structure or a stacked-layer structure. In FIG. 12, an insulating layer 255a, an insulating layer 255b over the insulating layer 255a, and an insulating layer 255c over the insulating layer 255b are illustrated as the insulating layer over the transistors. Note that the insulating layers (the insulating layers 255a to 255c) over the transistors may be regarded as part of the layer 101 including transistors.

Structure examples of the layer 101 including transistors will be described in Embodiment 4.

As each of the light-emitting devices 13R, 13G, and 13B, an organic light-emitting diode (OLED) or a quantum-dot light-emitting diode (QLED) is preferably used, for example. Examples of a light-emitting substance contained in the light-emitting device include a substance exhibiting fluorescent light (fluorescent material), a substance exhibiting phosphorescent light (phosphorescent material), a substance exhibiting thermally activated delayed fluorescence (thermally activated delayed fluorescent (TADF) material), and an inorganic compound (e.g., a quantum dot material). A light-emitting diode (LED) such as a micro-LED can also be used as the light-emitting device. Note that a liquid crystal element can be used as the light-emitting device. In the case where light-emitting layers containing quantum dots are used for the light-emitting devices 13R, 13G, and 13B, a structure related to the color conversion layer of the present invention can be employed as the structure related to the light-emitting layer. For example, in addition to the light-emitting layers containing quantum dots, a first inorganic film and a second inorganic film surrounding the light-emitting layers and a partition which separates the light-emitting layers can be provided. In the case where light-emitting layers containing quantum dots are used for the light-emitting devices 13R, 13G, and 13B, a structure related to the color conversion layer of the present invention can be employed for either or both the light-emitting layers and the color conversion layers 12R, 12G, and 12B. The color conversion layer is not necessarily provided and the structure related to the color conversion layer of the present invention is suitably used for the light-emitting layers containing quantum dots.

The emission color of the light-emitting devices 13R, 13G, and 13B can be infrared, red, green, blue, cyan, magenta, yellow, white, or the like. When the light-emitting device has a microcavity structure, the color purity can be increased.

The light-emitting devices 13R, 13G, and 13B each include a pair of electrodes and an EL layer (an organic compound layer) between the electrodes. Of the pair of electrodes of each of the light-emitting devices 13R, 13G, and 13B, it is preferable that a conductive film that transmits visible light be used for an electrode through which light is extracted and a conductive film that reflects visible light be used for an electrode through which light is not extracted.

One of the pair of electrodes of the light-emitting devices 13R, 13G, and 13B functions as an anode, and the other electrode functions as a cathode. The case where the pixel electrode functions as an anode and a common electrode functions as a cathode is described below as an example in some cases.

The light-emitting devices 13R, 13G, and 13B can emit white light, for example.

In the case where the light-emitting device 13R emits white light, it is preferable that the color conversion layer 12R convert blue and green light into red light and transmit red light. When the color conversion layer 12R overlaps with the light-emitting device 13R, blue- and green-light components of white light can be converted into a red-light component and extracted to the outside of the display device. Thus, the extraction efficiency of red light can be higher than that in the structure without the color conversion layer 12R. It is preferable that the color conversion layer 12R convert light having a shorter wavelength than red light (e.g., light from blue to orange) into red light and transmit red light.

Similarly, in the case where the light-emitting device 13G emits white light, it is preferable that the color conversion layer 12G convert blue light into green light and transmit green light. When the color conversion layer 12G overlaps with the light-emitting device 13G, a blue-light component of white light can be converted into a green-light component and extracted to the outside of the display device. Thus, the light extraction efficiency of green light can be higher than that in the structure without the color conversion layer 12G.

In the case where the light-emitting device 13B emits white light, the color conversion layer 12B that transmits blue light preferably overlaps with the light-emitting device 13B. Thus, a blue-light component of white light can be extracted to the outside of the display device.

In the case where the light-emitting device configured to emit white light has a microcavity structure, light with a specific wavelength (e.g., red, green, or blue) is sometimes intensified to be emitted.

For example, when the light-emitting devices 13R, 13G, and 13B emit white light and have a microcavity structure, red, green, and blue light can be obtained from the light-emitting devices 13R, 13G, and 13B, respectively.

Here, with the use of the microcavity structure, light with a desired wavelength can be intensified and extracted in the front direction; however, light extracted from the oblique direction may contain a white-light component.

Thus, the color conversion layers 12R and 12G are preferably provided also in the display device with a microcavity structure, in which case light extraction efficiency of a desired color can be increased.

The light-emitting devices 13R, 13G, and 13B can emit blue light, for example.

In the case where the light-emitting device 13R emits blue light, it is preferable that the color conversion layer 12R convert blue light into red light and transmit red light. When the color conversion layer 12R overlaps with the light-emitting device 13R, blue light emitted from the light-emitting device 13R can be converted into red light and extracted to the outside of the display device.

Similarly, in the case where the light-emitting device 13G emits blue light, it is preferable that the color conversion layer 12G convert blue light into green light and transmit green light. When the color conversion layer 12G overlaps with the light-emitting device 13G, blue light emitted from the light-emitting device 13G can be converted into green light and extracted to the outside of the display device.

That is, even when all of the light-emitting devices 13R, 13G, and 13B emit blue light, a full-color display device can be achieved.

Also in the case where the light-emitting devices 13R, 13G, and 13B emit blue light, a microcavity structure may be employed and blue light of the light-emitting devices may be intensified. Alternatively, a microcavity structure is not necessarily used.

The light-emitting devices 13R, 13G, and 13B may emit light with a shorter wavelength than blue light, for example, violet or ultraviolet light.

Here, examples of the light with a shorter wavelength than blue light include light with a peak wavelength in the emission spectrum of greater than or equal to 100 nm and less than 400 nm.

In the case where the light-emitting device 13B emits light with a shorter wavelength than blue light, it is preferable that the color conversion layer 12B which converts light of the light-emitting device 13B into blue light and transmits blue light overlap with the light-emitting device 13B. A coloring layer is preferably provided at a position overlapping with the light-emitting device 13B with the color conversion layer 12B therebetween.

As described above, also for the subpixel 11B emitting blue light, a color conversion layer or a combination of a color conversion layer and a coloring layer can be used.

Note that in the case where the light-emitting devices 13R and 13G emit light with a shorter wavelength than blue light, it is preferable that the color conversion layers 12R and 12G be also capable of converting light with a shorter wavelength than blue light into red or green light.

The light-emitting device of this embodiment may have either a single structure (a structure including only one light-emitting unit) or a tandem structure (a structure including a plurality of light-emitting units). The light-emitting unit includes at least one light-emitting layer.

In the case where a light-emitting device with a tandem structure that emits white light is used, for example, a structure including a light-emitting unit that emits blue light and a light-emitting unit that emits light with a longer wavelength than blue light can be employed. A charge-generation layer is preferably provided between the light-emitting units. A light-emitting device with the tandem structure can achieve high-luminance emission.

In the case where a light-emitting device with a tandem structure that emits blue light is used, for example, a structure including two or more light-emitting units that emit blue light can be employed. The light-emitting device may further include a light-emitting unit that emits light with a longer wavelength than blue light (e.g., a light-emitting unit that emits blue green or green light).

When the light-emitting device is manufactured by a method for processing an organic compound layer by a lithography method, the distance between adjacent light-emitting devices, adjacent EL layers, adjacent sidewall insulating layers, or adjacent pixel electrodes can be less than 10 μm, less than or equal to 8 μm, less than or equal to 5 μm, less than or equal to 3 μm, less than or equal to 2 μm, less than or equal to 1.5 μm, less than or equal to 1 μm, or even less than or equal to 0.5 μm. Using a light exposure apparatus for LSI can further shorten the distance between adjacent light-emitting devices, adjacent EL layers, adjacent sidewall insulating layers, or adjacent pixel electrodes to 500 nm or less, 200 nm or less, 100 nm or less, or even 50 nm or less, for example, in a process over a Si wafer. However, when the width between the light-emitting devices is narrow, light leakage might occur. In order to narrow the distance between the color conversion layers, the partition 20 needs to be narrowed; thus, when the color conversion layer is formed by coating, the color conversion layer might cross over the partition 20 and enter an adjacent pixel.

In view of this, as illustrated in FIG. 1B, end portions of the color conversion layers 12R, 12G, and 12B are preferably inward from end portions of the light-emitting devices 13R, 13G, and 13B (end portions of the pixel electrodes). In this case, in a sidewall of the partition 20, any of the color conversion layers 12R, 12G, and 12B, the first inorganic film 21, the second inorganic film 22, and any of the light-emitting devices 13R, 13G, and 13B overlap with each other. When the end portions of the color conversion layers 12R, 12G, and 12B are inward from the end portions of the light-emitting devices 13R, 13G, and 13B, the partition 20 does not need to be excessively narrowed; thus, the possibility that the color conversion layer crosses over the partition and enters an adjacent pixel can be reduced when the color conversion layer is formed by coating. In addition, light leakage can be reduced.

Embodiment 5 can be referred to for more detailed description of the structure and the materials of the light-emitting device.

Note that for simplification of the drawing, the unit 31 is sometimes omitted in drawings in the following description.

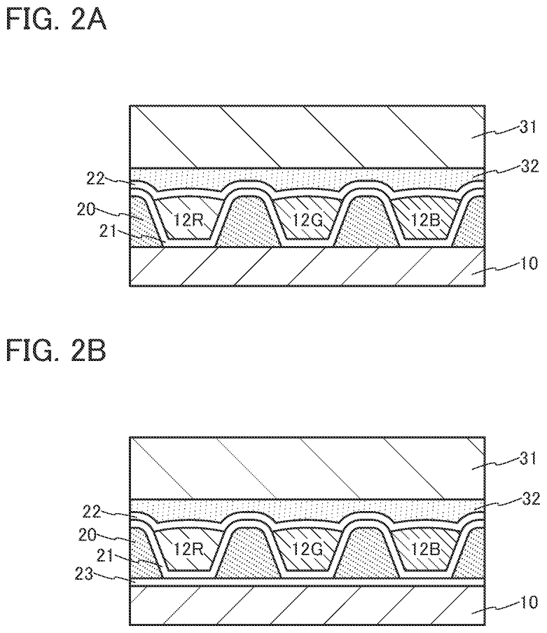

FIGS. 2A and 2B, FIGS. 3A to 3C, FIGS. 4A and 4B, FIGS. 5A and 5B, and FIGS. 6A and 6B are variation examples of the cross-sectional view in FIG. 1B.

In the cross-sectional view in FIG. 2A, in addition to the components in FIG. 1B, the first inorganic film 21 includes a portion over the partition 20 and the second inorganic film 22 includes a portion over the partition 20 and the first inorganic film 21. In that case, the side surface and a top surface of the partition 20 are covered with the first inorganic film 21 and the second inorganic film 22; thus, diffusion of constituent elements not only from the side surface of the partition 20 but also from the top surface of the partition 20 can be prevented. Accordingly, the effect of inhibiting deterioration of the color conversion layers 12R, 12G, and 12B can be further increased by the first inorganic film 21 and the second inorganic film 22. Therefore, a higher reliable display device can be obtained.

Note that in the structure in FIG. 2A, in each subpixel, the first inorganic film 21, any of the color conversion layers 12R, 12G, and 12B, and the second inorganic film 22 overlap with one another. In other words, the partition 20, the first inorganic film 21, and the second inorganic film 22 overlap with one another between the subpixels. It can also be said that any of the color conversion layers 12R, 12G, and 12B is between the first inorganic film 21 and the second inorganic film 22 in each subpixel. In addition, between the subpixels, it can also be said that the first inorganic film 21 is between the partition 20 and the second inorganic film 22. Without limitation to these expressions, drawings can be referred to for the structure. The same applies to the other drawings.

The cross-sectional view in FIG. 2B includes the third inorganic film 23 in addition to the components in FIG. 2A. The third inorganic film 23 includes a portion between the substrate 10 and the partition 20 and a portion between the substrate 10 and the first inorganic film 21. With the third inorganic film 23, the periphery of the partition 20 is surrounded by the first inorganic film 21, the second inorganic film 22, and the third inorganic film 23. Thus, even when the constituent element is released from the side surface of the partition 20, the constituent element is confined in a region surrounded by the first inorganic film 21, the second inorganic film 22, and the third inorganic film 23, so that the constituent element can be surely prevented from diffusing to the periphery. Accordingly, the effect of inhibiting deterioration of the color conversion layers 12R, 12G, and 12B can be further increased. Therefore, a higher reliable display device can be obtained.

Note that the structure illustrated in FIG. 2B can be regarded as the third inorganic film 23, the first inorganic film 21, any of the color conversion layers 12R, 12G, and 12B, and the second inorganic film 22 overlap with one another in each subpixel. In other words, the third inorganic film 23, the partition 20, the first inorganic film 21, and the second inorganic film 22 overlap with one another between the subpixels. It can also be said that any of the color conversion layers 12R, 12G, and 12B is positioned between the first inorganic film 21 and the second inorganic film 22 in each subpixel. In addition, between the subpixels, it can also be said that the first inorganic film 21 is positioned between the third inorganic film 23 and any of the color conversion layers 12R, 12G, and 12B. Moreover, between the subpixels, it can also be said that the first inorganic film 21 is positioned between the partition 20 and the second inorganic film 22. Without limitation to these expressions, drawings can be referred to for the structure. The same applies to the other drawings.

For the third inorganic film 23, a material similar to those for the first inorganic film 21 and the second inorganic film 22 can be used.

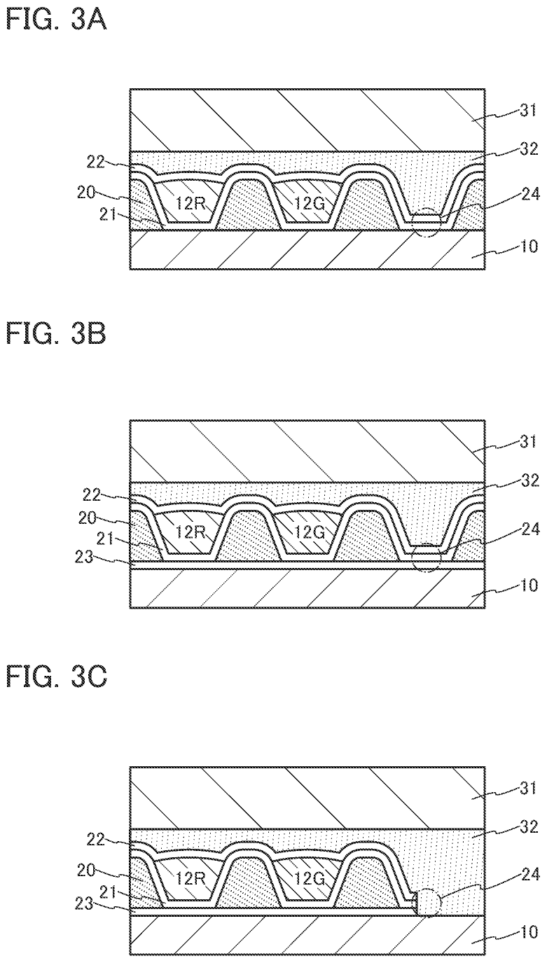

In a cross-sectional view in FIG. 3A, the color conversion layer 12B in FIG. 2A is not provided. For example, in the case where the subpixel 11B is a blue subpixel and the light-emitting devices 13R, 13G, and 13B emit blue light, the color of light emitted from the light-emitting device 13B is not necessarily converted by the color conversion layer 12B; thus, the color conversion layer 12B is not necessarily provided in the subpixel 11B. In that case, in a region 24, the first inorganic film 21 and the second inorganic film 22 are preferably in contact with each other. In that case, diffusion of the constituent elements of the partition 20 from the partition 20 can be prevented, so that the effect of inhibiting deterioration of the color conversion layers 12R and 12G can be further increased by the first inorganic film 21 and the second inorganic film 22.

As in FIG. 3A, in a cross-sectional view in FIG. 3B, the color conversion layer 12B in FIG. 2A is not provided. In that case, in the region 24, the first inorganic film 21 is preferably in contact with the second inorganic film 22 and the third inorganic film 23. In that case, diffusion of the constituent elements of the partition 20 from the partition 20 can be prevented, so that the effect of inhibiting deterioration of the color conversion layers 12R and 12G can be further increased.

In a cross-sectional view in FIG. 3C, the first inorganic film 21, the second inorganic film 22, and the third inorganic film 23 are removed from the region 24 in FIG. 3B. In that case, the resin layer 32 is in contact with the substrate 10, so that adhesion between the unit 30 and the unit 31 can be improved. For example, only the first inorganic film 21 and the second inorganic film 22 which are in the region 24 may be removed and the third inorganic film is not necessarily removed. In this case, the resin layer 32 and the third inorganic film 23 are in contact with each other. Alternatively, only the first inorganic film 21 in the region 24 may be removed, and the second inorganic film 22 and the third inorganic film 23 are not necessarily removed. In this case, the resin layer 32 and the second inorganic film 22 are in contact with each other. Alternatively, only the second inorganic film 22 in the region 24 may be removed and the first inorganic film 21 and the third inorganic film 23 are not necessarily removed. In this case, the resin layer 32 and the first inorganic film 21 are in contact with each other.

In FIGS. 3A to 3C, the region 24 may be provided in a portion other than the blue subpixel. For example, the region 24 may be provided to surround the periphery of a pixel region. In the case where the periphery of the pixel region is surrounded, entry of impurities from the outside of the pixel region into the pixel region can be inhibited. The region 24 may be provided between the pixel region and a peripheral region (e.g., a driver circuit region). The region 24 may be provided in a band shape or a plurality of regions 24 may be provided with a space therebetween. In the case where the plurality of regions 24 are included, the widths of the regions 24 may be different from one another.

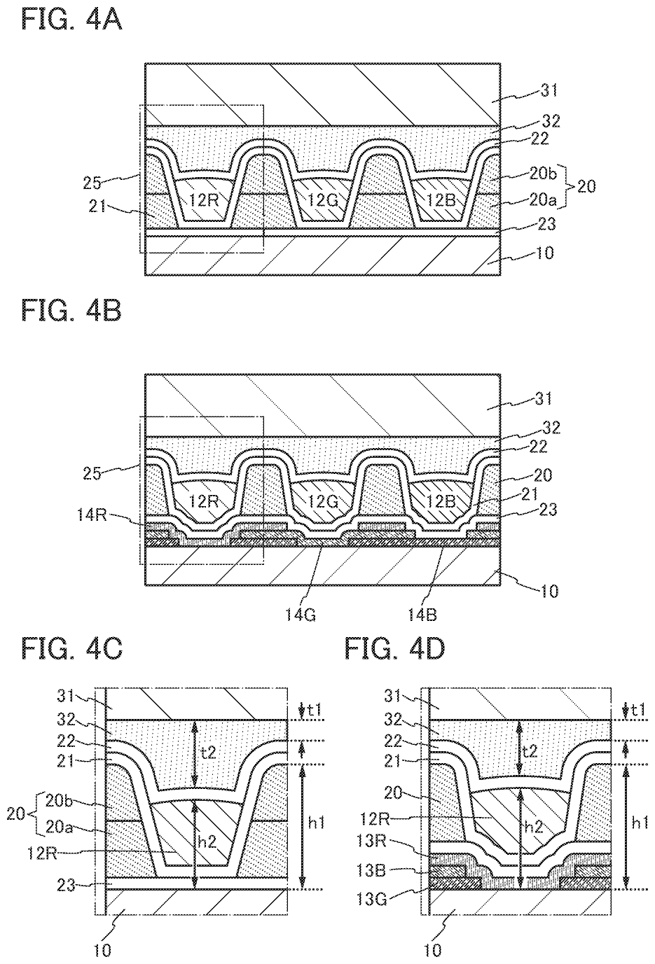

In a cross-sectional view in FIG. 4A, the height of the partition 20 is higher than that in FIG. 2A. For example, when the partition 20 has a stacked-layer structure of partitions 20a and 20b, the height can be further increased. In this case, the height from a top surface of the substrate 10 to the top surface of the partition 20 is higher than the height from the top surface of the substrate 10 to the top surface of each of the color conversion layers 12R, 12G, and 12B. The height from a top surface of the second inorganic film 22 which is positioned over the color conversion layer to the unit 31 is higher than the height from the top surface of the second inorganic film 22 which is positioned over the partition 20 to the unit 31. Accordingly, adjacent color conversion layers can be further separated from each other with the partition 20.

For specific description, FIG. 4C illustrates an enlarged view of a region 25 in FIG. 4A. As illustrated in FIG. 4C, when the height from the top surface of the substrate 10 to the top surface of the partition 20 is h1, the height from the top surface of the substrate 10 to the top surface of the color conversion layer 12R is h2, the height from the top surface of the second inorganic film 22 which is positioned over the color conversion layer to the unit 31 is t2, and the height from the top surface of the second inorganic film 22 which is positioned over the partition 20 to the unit 31 is t1, adjacent color conversion layers can be further separated from each other in the case where h1 is higher than h2 (h1>h2) or t2 is higher than t1 (t2>t1). Although FIG. 4C illustrates the color conversion layer 12R as an example, the present invention is not limited thereto, and the same applies to the color conversion layer 12G or 12B.

In a cross-sectional view in FIG. 4B, in addition to the components in FIG. 2A, coloring layers 14R, 14G, and 14B transmitting red, green, and blue light are provided in the subpixels 11R, 11G, and 11B, respectively. In more detail, coloring layers of different colors (the coloring layers 14R, 14G, and 14B) are provided between the substrate 10 and the third inorganic film 23. In some cases, part of light emitted from the light-emitting device is transmitted through the color conversion layer without being converted. When light transmitted through the color conversion layer is extracted through the coloring layer, light other than light of the objective color can be absorbed by the coloring layer, and color purity of light exhibited by a subpixel can be improved.

In FIG. 4B, it is preferable that the coloring layers overlap with each other in a region overlapping with the partition 20. Also in this case, the height from the top surface of the substrate 10 to the top surface of the partition 20 is higher than the height from the top surface of the substrate 10 to the top surface of each of the color conversion layers 12R, 12G, and 12B. The height from the top surface of the second inorganic film 22 which is positioned over the color conversion layer to the unit 31 is higher than the height from the top surface of the second inorganic film 22 which is positioned over the partition 20 to the unit 31. Accordingly, adjacent color conversion layers can be further separated from each other with the partition 20.

For specific description, FIG. 4D illustrates an enlarged view of the region 25 in FIG. 4B. As illustrated in FIG. 4C, when the height from the top surface of the substrate 10 to the top surface of the partition 20 is h1, the height from the top surface of the substrate 10 to the color conversion layer 12R is h2, the height from the top surface of the second inorganic film 22 which is positioned over the color conversion layer to the unit 31 is t2, and the height from the top surface of the second inorganic film 22 which is positioned over the partition 20 to the unit 31 is t1, adjacent color conversion layers can be further separated from each other by the partition 20 in the case where h1 is higher than h2 (h1>h2) or t2 is higher than t1 (t2>t1). Although FIG. 4D illustrates the color conversion layer 12R as an example, the present invention is not limited thereto, and the same applies to the color conversion layer 12G or 12B.

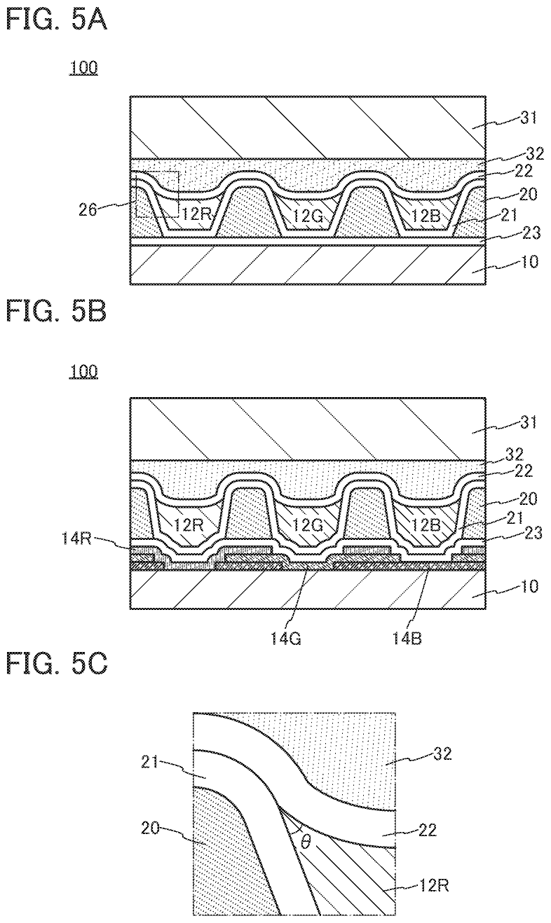

In a cross-sectional view in FIG. 5A, the top surfaces of the color conversion layers 12R, 12G, and 12B are depressed in the structure illustrated in FIG. 2A. When the top surfaces of the color conversion layers are depressed, unevenness around a boundary between the color conversion layer and the partition 20 is reduced (or the step is eliminated); thus, the coverage with the second inorganic film 22 is improved and the effect of inhibiting deterioration of the color conversion layers 12R and 12G can be further increased. In the case where unevenness of the surface where the second inorganic film 22 is provided is not reduced, the second inorganic film 22 might be disconnected. When the top surface of the color conversion layer is depressed, unevenness around a boundary between the color conversion layer and the partition 20 is reduced; thus, the second inorganic film 22 can be inhibited from being disconnected. Note that a depressed surface can be referred to as a depressed curved surface.

For specific description, FIG. 5C illustrates an enlarged view of a region 26 in FIG. 5A. As illustrated in FIG. 4C, when the angle formed by a boundary surface between the color conversion layer 12R and the first inorganic film 21 and a boundary surface between the color conversion layer 12R and the second inorganic film 22 is θ, θ is preferably an acute angle. Specifically, when θ is greater than or equal to 0° and less than or equal to 90°, preferably greater than or equal to 0° and less than or equal to 45°, unevenness around a boundary between the color conversion layer 12R and the partition 20 is reduced, which can increase the coverage with the second inorganic film 22 and further increase the effect of inhibiting the deterioration of the color conversion layers 12R and 12G.

Note that in this structure, the deterioration of the color conversion layers 12R and 12G can be effectively inhibited because the coverage with the second inorganic film 22 is improved. Thus, in the case where the effect of inhibiting deterioration by the second inorganic film 22 is sufficient, the first inorganic film 21 and the third inorganic film 23 may be formed or are not necessarily formed. In the case where the first inorganic film 21 is not formed, an angle formed by the boundary surface between the color conversion layer 12R and the partition 20 and the boundary surface between the color conversion layer 12R and the second inorganic film 22 can be θ.

Although FIG. 5C illustrates the color conversion layer 12R as an example, the present invention is not limited thereto, and the same applies to the color conversion layer 12G or 12B.

In a cross-sectional view in FIG. 5B, the top surfaces of the color conversion layers 12R, 12G, and 12B are depressed in the structure in FIG. 4B. In this case, for example, in the direction from the partition 20 toward the color conversion layer 12R, a gentle slope is formed on the surface of the coloring layer 14R by the step between the coloring layers 14G and 14B. The first inorganic film 21 and the color conversion layer 12R are formed to be gently sloped. Thus, a bottom surface of the color conversion layer 12R is positioned below a bottom surface of the partition 20. As a result, θ is easy to control to have a suitable value.

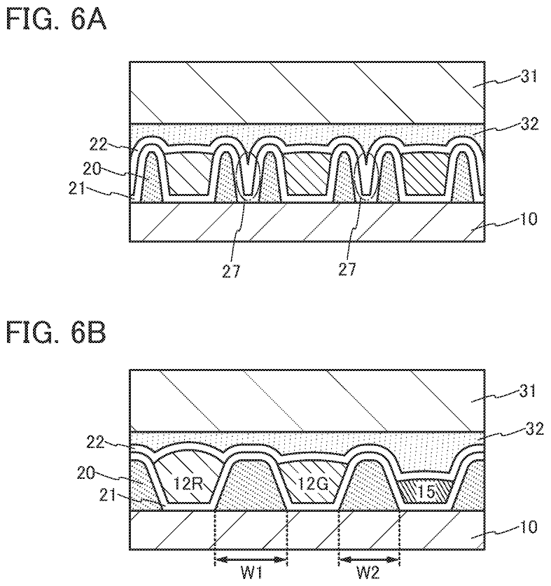

In a cross-sectional view in FIG. 6A, a groove 27 is provided in the partition 20 in the structure in FIG. 2A. When the color conversion layer is formed by coating, even when a solution to be the color conversion layer spills from the opening of the partition 20, the solution flows into the groove 27 first; thus, the solution cannot flow into an adjacent opening.

To increase the effect, the groove 27 can be provided to surround the opening in the top view. Note that the groove 27 does not necessarily have a shape such that the opening is surrounded completely, and only a hole into which the solution to be the color conversion layer flows when the solution spills from the opening may be provided. In the case where the opening is not completely surrounded, a display region may be widened as compared with the case where the opening is completely surrounded. Note that the opening may be narrowed by the groove 27. In view of this, when the groove 27 is formed in the partition 20, the partition 20 is not completely removed and the depressed portion is formed in the upper portion of the partition 20, so that the display region may be widened.

Note that when the groove 27 overlaps with a wiring (e.g., a source/drain wiring, a gate wiring, a power supply line, and a touch panel wiring) in the unit 31, the display region is less likely to be narrowed.

The width of the groove 27 is preferably changed depending on the thickness of the color conversion layer. When the color conversion layer is thick, the solution to be the color conversion layer is more likely to be spilled from the opening and the amount of spilled solution is increased when the solution is spilled. Thus, it is effective to increase the width of the groove 27 when the color conversion layer is thick.

Note that the first inorganic film 21 and the second inorganic film 22 are in contact with each other in the groove 27, whereby diffusion of oxygen can be prevented.

Note that in FIG. 6A, in the case where deterioration of the color conversion layer does not need to be inhibited or is inhibited by another means, the first inorganic film 21 and the second inorganic film 22 are not necessarily formed.

In a cross-sectional view of FIG. 6B, the thickness of the color conversion layer is changed for every color. The particle size of quantum dots needs to be large when light is desired to be converted into light with a longer wavelength; thus, in the case where the number of the particles of quantum dots of the color conversion layers of different colors is the same, the thickness of the color conversion layer is changed for every color. For example, the color conversion layer 12R converts light of the light-emitting device 13R into red light, and the color conversion layer 12G converts light of the light-emitting device 13G into green light; thus, when the thickness of the color conversion layer 12R is greater than that of the color conversion layer 12G, the number of the particles of quantum dots can be the same.

Note that in the case where the color conversion layer is desired to be thick, the solution to be the color conversion layer is more likely to be spilled from the opening of the partition 20 when the color conversion layer is formed by coating. In view of this, the width of the partition 20 around the thick color conversion layer (e.g., the color conversion layer 12R) is preferably larger than that of the partition 20 around the other color conversion layers. Thus, the solution to be the color conversion layer 12R is less likely to be spilled from the opening of the partition 20.

In the cross-sectional view in FIG. 6B, a thickness adjustment layer 15 is provided instead of the color conversion layer 12B in the structure in FIG. 2A. For example, in the case where the subpixel 11B is a blue subpixel and the light-emitting devices 13R, 13G, and 13B emit blue light, the color of light emitted from the light-emitting device 13B is not necessarily converted by the color conversion layer 12B; thus, the color conversion layer 12B is not necessarily provided in the subpixel 11B. Meanwhile, in the case where the color conversion layer 12B is not provided, unevenness of the unit 30 increases, which might decrease adhesion between the unit 30 and the unit 31 when the unit 30 and the unit 31 are bonded to each other. In view of this, the thickness adjustment layer 15 is provided instead of the color conversion layer 12B. In that case, the thickness of the thickness adjustment layer 15 is not necessarily as great as those of the color conversion layers 12R and 12G as long as the unevenness of the unit 30 can be reduced. When the thickness of the thickness adjustment layer 15 is less than those of the color conversion layers 12R and 12G, a solution to be the thickness adjustment layer 15 might not cross over the partition 20 when the solution is applied. Thus, the width of the partition 20 around the thickness adjustment layer 15 may be small, in which case the display region of the subpixel 11B can be increased.

Note that in the structure illustrated in FIG. 6B, in the case where deterioration of the color conversion layer does not need to be inhibited or is inhibited by another means, the first inorganic film 21 and the second inorganic film 22 are not necessarily formed.

As described above, in the display device of one embodiment of the present invention, entry of impurities such as oxygen into the color conversion layer can be prevented by providing an inorganic film surrounding the color conversion layer, for example. Accordingly, a display device having high display quality can be provided.

This embodiment can be combined with any of the other embodiments as appropriate. In this specification, in the case where a plurality of structure examples are shown in one embodiment, the structure examples can be combined as appropriate.

### Embodiment 2

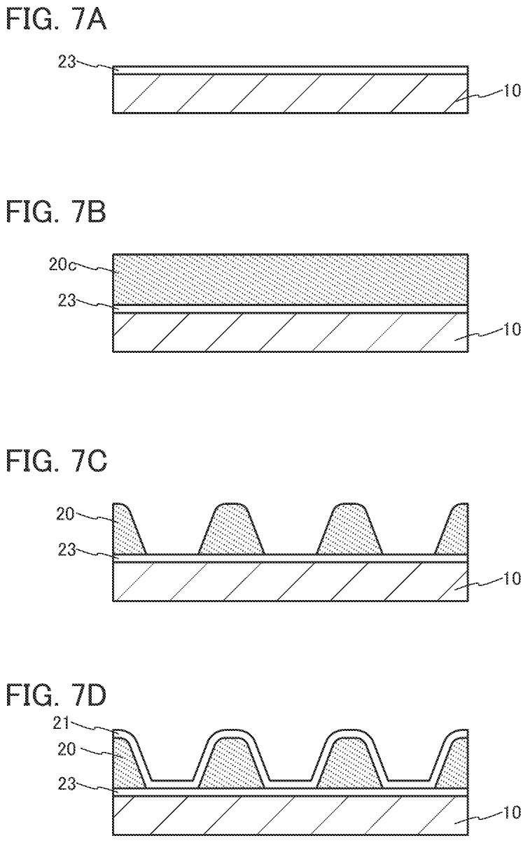

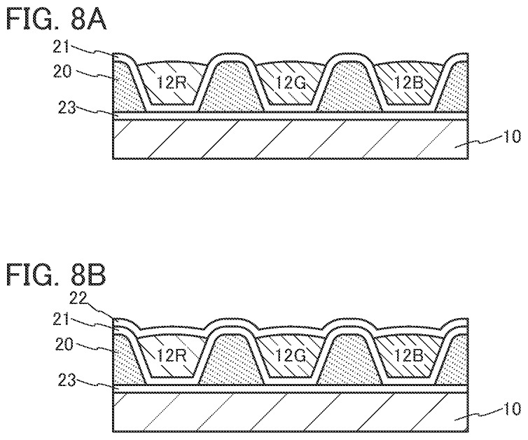

In this embodiment, a method for manufacturing a display device of one embodiment of the present invention will be described with reference to FIGS. 7A to 7D and FIGS. 8A and 8B. Note that as for a material and a formation method of each component, portions similar to those described in Embodiment 1 are not described in some cases. The structure of the light-emitting device will be described in detail in Embodiment 5.

FIGS. 7A to 7D and FIGS. 8A and 8B illustrate a method for manufacturing the unit 30 included in the structure in FIG. 2B as an example of a method for manufacturing a display device of one embodiment of the present invention.

Note that thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic CVD (MOCVD) method.

Alternatively, thin films included in the display device (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, screen printing (stencil), offset printing (planography), flexography (relief printing), gravure printing, or micro-contact printing), or the like.

Thin films included in the display device can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion exposure technique. As the light for exposure, extreme ultraviolet (EUV) light or X-rays may also be used. Furthermore, instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

First, the third inorganic film 23 is formed over the substrate 10 (FIG. 7A).

Next, an insulating film 20c to be the partition 20 is formed over the third inorganic film 23 (FIG. 7B). For example, the insulating film 20c can be formed by a wet film formation method such as spin coating, dipping, spray coating, ink-jetting, dispensing, screen printing, offset printing, doctor blade coating, slit coating, roll coating, curtain coating, or knife coating. The structure applicable to the partition 20 described in Embodiment 1 can be employed for the insulating film 20c.

Next, the insulating film 20c is processed to form the partition 20 having openings (FIG. 7C). The insulating film 20c can be processed by a photolithography method.

Then, the first inorganic film 21 is formed over the third inorganic film 23 and the partition 20 (FIG. 7D).

Next, the color conversion layers 12R, 12G, and 12B are formed in the openings of the partition 20 (FIG. 8A).

Then, the second inorganic film 22 is formed over the color conversion layers 12R, 12G, and 12B and the first inorganic film 21 (FIG. 8B), whereby the unit 30 can be formed.

When the unit 30 formed in this manner is bonded to the unit 31 with the resin layer 32 therebetween, the display device can be manufactured.

As described above, in the method for manufacturing a display device of this embodiment, the color conversion layers are formed after the partition is provided over the substrate 10, whereby color conversion layers that prevent color mixture can be easily formed. Deterioration of the color conversion layers can be prevented by the first inorganic film 21, the second inorganic film 22, and the third inorganic film 23. Accordingly, a display device having high display quality can be provided.

This embodiment can be combined with any of the other embodiments as appropriate.

### Embodiment 3

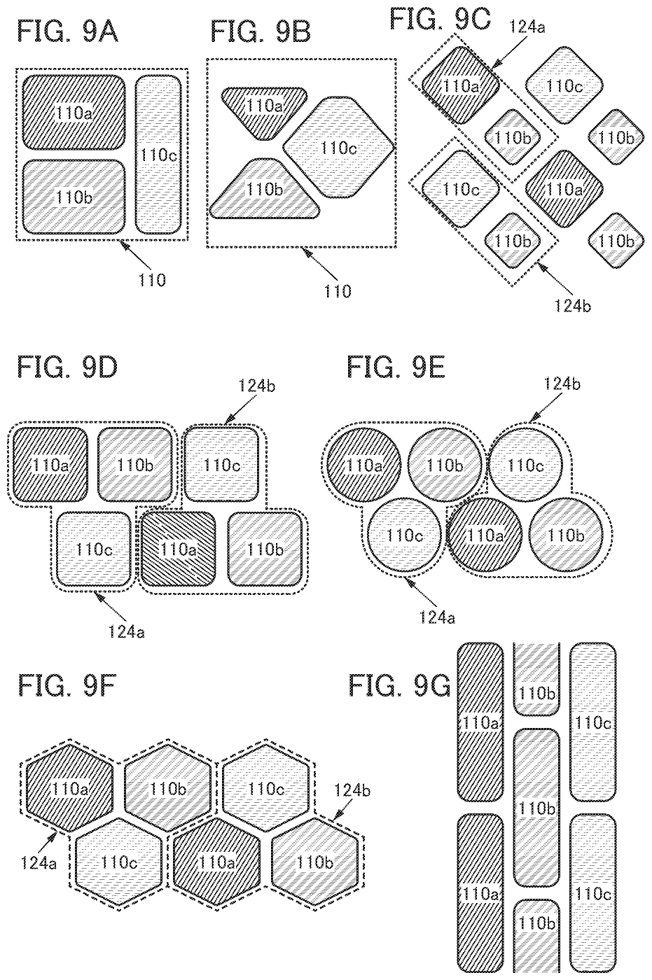

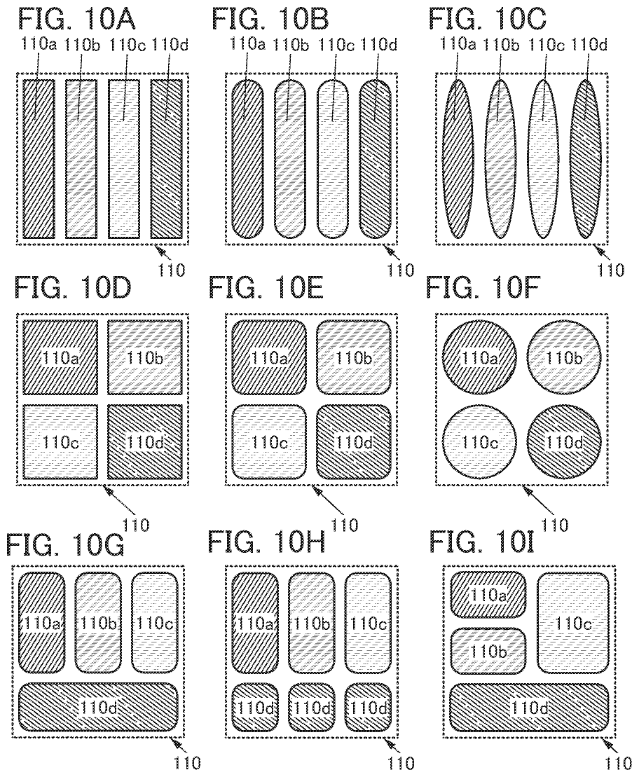

In this embodiment, a display device of one embodiment of the present invention will be described with reference to FIGS. 9A to 9G and FIGS. 10A to 10I.

### [Pixel Layout]

In this embodiment, pixel layouts different from those in FIG. 1A will be mainly described. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

The top surface shape of the subpixel illustrated in the diagrams in this embodiment corresponds to the top surface shape of a light-emitting region.

Examples of the top surface shape of the subpixel include polygons such as a triangle, a tetragon (including a rectangle, a rhombus, and a square), and a pentagon; polygons with rounded corners; an ellipse; and a circle.

The circuit constituting the subpixel is not necessarily placed within the dimensions of the subpixel illustrated in the diagrams and may be placed outside the subpixel.

The pixel 110 illustrated in FIG. 9A employs S-stripe arrangement. The pixel 110 illustrated in FIG. 9A consists of three types of subpixels 110a, 110b, and 110c.

The pixel 110 illustrated in FIG. 9B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b illustrated in FIG. 9C employ PenTile arrangement. FIG. 9C illustrates an example where the pixels 124a including the subpixels 110a and 110b and the pixels 124b including the subpixels 110b and 110c are alternately arranged.

The pixels 124a and 124b illustrated in FIGS. 9D and 9F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 9D illustrates an example where the top surface of each subpixel has a rough tetragonal shape with rounded corners, FIG. 9E illustrates an example where the top surface of each subpixel has a circular shape, and FIG. 9F illustrates an example where the top surface of each subpixel has a rough hexagonal shape with rounded corners.

In FIG. 9F, each subpixel is provided inside one of the closest-packed hexagonal regions. Focusing on one of the subpixels, the subpixel is placed so as to be surrounded by six subpixels. In addition, the subpixels are arranged such that subpixels exhibiting the same color are not adjacent to each other. For example, focusing on the subpixel 110a, three subpixels 110b and three subpixels 110c are arranged to surround the subpixel 110a, so that the subpixel 110a, the subpixel 110b, and the subpixel 110c are alternately arranged.

FIG. 9G illustrates an example where subpixels of different colors are arranged in a zigzag manner. Specifically, the positions of the top sides of two subpixels arranged in the row direction (e.g., the subpixels 110a and 110b or the subpixels 110b and 110c) are not aligned in the top view.

For example, in each pixel in FIGS. 9A to 9G, it is preferable that the subpixel 110a be a subpixel R emitting red light, the subpixel 110b be a subpixel G emitting green light, and the subpixel 110c be a subpixel B emitting blue light. Note that the structures of the subpixels are not limited to this, and the colors and arrangement order of the subpixels can be determined as appropriate. For example, the subpixel 110b may be the subpixel R emitting red light and the subpixel 110a may be the subpixel G emitting green light.

In the case where the light-emitting device is manufactured by a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a pixel electrode may have a polygonal shape with rounded corners, an elliptical shape, a circular shape, or the like. In the display device of one embodiment of the present invention, top surface shapes of the EL layer and the light-emitting device may each have a polygonal shape with rounded corners, an elliptical shape, a circular shape, or the like by the influence of the top surface of the pixel electrode.

To obtain a desired top surface shape of the pixel electrode, a technique of correcting a mask pattern in advance so that a transferred pattern agrees with a design pattern (an optical proximity correction (OPC) technique) may be used. Specifically, with the OPC technique, a pattern for correction is added to a corner portion or the like of a figure on a mask pattern.

As illustrated in FIGS. 10A to 10I, the pixel can include four types of subpixels.

The pixels 110 illustrated in FIGS. 10A to 10C each employ S-stripe arrangement.

FIG. 10A illustrates an example where each subpixel has a rectangular top surface shape, FIG. 10B illustrates an example where each subpixel has a top surface shape formed by combining two half circles and a rectangle, and FIG. 10C illustrates an example where each subpixel has an elliptical top surface shape.

The pixels 110 illustrated in FIGS. 10D to 10F each employ matrix arrangement.

FIG. 10D illustrates an example where each subpixel has a square top surface shape, FIG. 10E illustrates an example where each subpixel has a rough square top surface shape with rounded corners, and FIG. 10F illustrates an example where each subpixel has a circular top surface shape.

FIGS. 10G and 10H each illustrate an example where one pixel 110 is composed of two rows and three columns.

The pixel 110 illustrated in FIG. 10G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 10H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Matching the positions of the subpixels in the upper row and the lower row as illustrated in FIG. 10H enables dust and the like that would be produced in the manufacturing process to be removed efficiently. Thus, a display device having high display quality can be provided.

FIG. 10I illustrates an example where one pixel 110 is composed of three rows and two columns.

The pixel 110 illustrated in FIG. 10I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIGS. 10A to 10I each include four types of subpixels 110a, 110b, 110c, and 110d.

The subpixels 110a, 110b, 110c, and 110d include light-emitting devices that emit light of different colors. The subpixels 110a, 110b, 110c, and 110d can be of four colors of R, G, B, and white (W), of four colors of R, G, B, and Y, or of R, G, B and infrared (IR) light, for example.

In the pixels 110 illustrated in FIGS. 10A to 10I, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIGS. 10G and 10H, leading to an increase in the display quality. In the pixel 110 illustrated in FIG. 10I, what is called S stripe arrangement is employed as the layout of R, G, and B, leading to higher display quality.

As described above, the pixel composed of the subpixels each including the light-emitting device can employ any of a variety of layouts in the display device of one embodiment of the present invention.

This embodiment can be combined with any of the other embodiments as appropriate.

### Embodiment 4

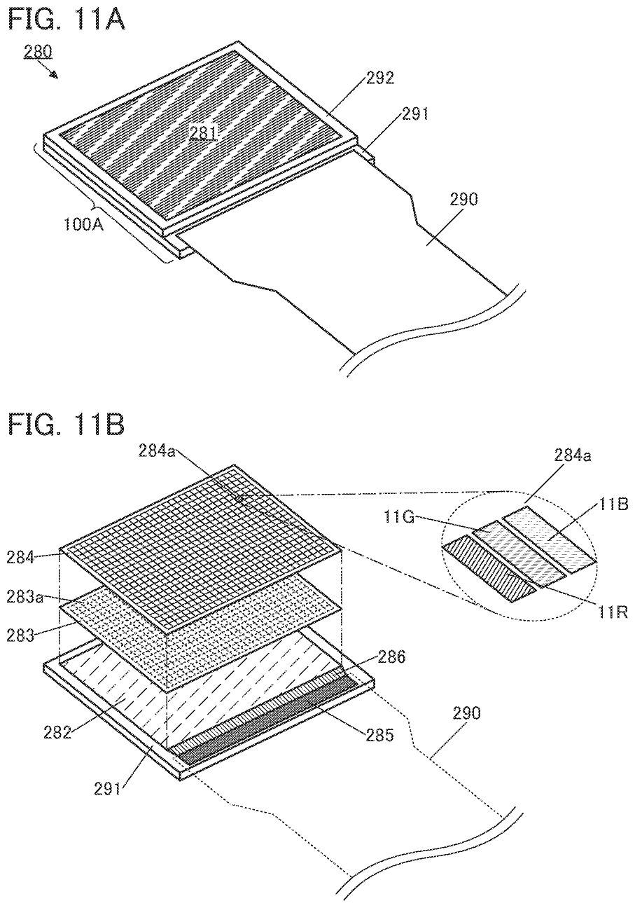

In this embodiment, display devices of embodiments of the present invention will be described with reference to FIGS. 11A and 11B, FIG. 12, FIGS. 13A to 13F, FIGS. 14A to 14D, FIG. 15, and FIGS. 16A to 16D.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display device in this embodiment can be a high-definition display device or a large-sized display device. Accordingly, the display device in this embodiment can be used for display portions of electronic appliances such as a digital camera, a digital video camera, a digital photo frame, a mobile phone, a portable game console, a portable information terminal, and an audio reproducing device, in addition to display portions of electronic appliances with a relatively large screen, such as a television device, a desktop or laptop personal computer, a monitor of a computer or the like, digital signage, and a large game machine such as a pachinko machine.

### [Display Module]

FIG. 11A is a perspective view of a display module 280. The display module 280 includes a display device 100A and an FPC 290.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 11B. The pixel 284a can employ any of the structures described in the above embodiments. FIG. 11B illustrates an example where a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have greatly high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a device for VR such as an HMD or a glasses-type device for AR. For example, even in the case of a structure in which the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic appliances including a relatively small display portion. For example, the display module 280 can be suitably used in a display portion of a wearable electronic appliance, such as a wrist watch.

### [Display Device 100A]

The display device 100A illustrated in FIG. 12 includes a substrate 301, the light-emitting devices 13R, 13G, and 13B, the color conversion layers 12R, 12G, and 12B, a capacitor 240, and a transistor 310.

The subpixels 11R, 11G, and 11B in FIG. 11B include the light-emitting devices 13R, 13G, and 13B and the color conversion layers 12R, 12G, and 12B, respectively. In the subpixel 11R, light emitted from the light-emitting device 13R is extracted as red light (R) to the outside of the display device 100A through the color conversion layer 12R. Similarly, in the subpixel 11G, light emitted from the light-emitting device 13G is extracted as green light (G) to the outside of the display device 100A through the color conversion layer 12G. Similarly, in the subpixel 11B, light emitted from the light-emitting device 13B is extracted as blue light (B) to the outside of the display device 100A through the color conversion layer 12B.

The substrate 301 corresponds to the substrate 291 in FIGS. 11A and 11B. A stacked-layer structure including the substrate 301 and the components thereover up to the insulating layer 255c corresponds to the layer 101 including transistors in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311 and functions as an insulating layer.

An element isolation layer 315 is provided between two adjacent transistors 310 so as to be embedded in the substrate 301.

Furthermore, an insulating layer 261 is provided to cover the transistor 310, and the capacitor 240 is provided over the insulating layer 261.

The capacitor 240 includes conductive layers 241 and 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101 including transistors. The conductive layer can be referred to as a guard ring. By providing the conductive layer, elements such as a transistor and a light-emitting device can be inhibited from being broken by high voltage application due to electrostatic discharge (ESD) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting devices 13R, 13G, and 13B are provided over the insulating layer 255c.

Pixel electrodes included in the light-emitting devices 13R, 13G, and 13B are electrically connected to one of the source and the drain of the transistor 310 through a plug 256 embedded in the insulating layers 243, 255a, 255b, and 255c, the conductive layer 241 embedded in the insulating layer 254, and the plug 271 embedded in the insulating layer 261. A surface that is of the insulating layer 255c and is in contact with the pixel electrode and a surface that is of the plug 256 and is in contact with the pixel electrode are level with or substantially level with each other. Any of a variety of conductive materials can be used for the plugs.

Although not illustrated, a protective layer is preferably provided over the light-emitting devices 13R, 13G, and 13B. The color conversion layers 12R, 12G, and 12B are respectively provided at positions overlapping with the light-emitting devices 13R, 13G, and 13B. The substrate 10 is bonded onto the color conversion layers 12R, 12G, and 12B with the resin layer 32. Embodiment 1 can be referred to for the details of the light-emitting devices and the components thereover up to the substrate 10. The substrate 10 corresponds to the substrate 292 in FIG. 11A.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

It is preferable that a semiconductor layer of a transistor contain a metal oxide (also referred to as an oxide semiconductor). That is, a transistor including a metal oxide in its channel formation region (hereinafter also referred to as an OS transistor) is preferably used in the display device of this embodiment.

As the oxide semiconductor having crystallinity, a c-axis aligned crystalline oxide semiconductor (CAAC-OS), a nanocrystalline oxide semiconductor (nc-OS), and the like are given.

Alternatively, a transistor containing silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows simplification of an external circuit mounted on the display device and a reduction in costs of parts and mounting costs.

The OS transistor has much higher field-effect mobility than a transistor containing amorphous silicon. In addition, the OS transistor has an extremely low leakage current between a source and a drain in an off state (hereinafter also referred to as off-state current), and electric charge accumulated in a capacitor that is connected in series to the transistor can be held for a long period. Furthermore, the power consumption of the display device can be reduced with the OS transistor.

To increase the emission luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor in the pixel circuit, a current flowing between the source and the drain can be set minutely in accordance with a change in gate-source voltage; hence, the amount of current flowing through the light-emitting device can be controlled. Accordingly, the gray level in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, with use of an OS transistor as a driving transistor included in the pixel circuit, it is possible to achieve “inhibition of black floating”, “increase in emission luminance”, “increase in gray level”, “inhibition of variation in light-emitting devices”, and the like.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

This embodiment can be combined with any of the other embodiments as appropriate.

### Embodiment 5

In this embodiment, a light-emitting device that can be used in the display device of one embodiment of the present invention will be described.

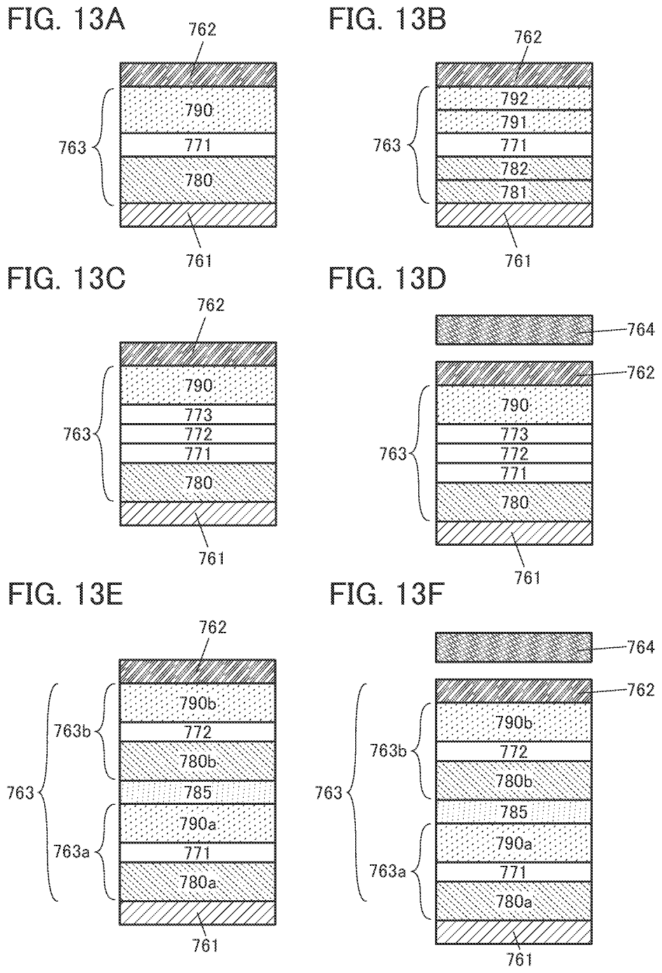

As illustrated in FIG. 13A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

For the lower electrode 761 and the upper electrode 762, “lower” and “upper” are based on a vertical relation assuming that the layer 101 including transistors is on the lower side and the substrate 10 is on the upper side (e.g., FIG. 12).

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 13A is referred to as a single structure in this specification.

FIG. 13B is a variation example of the EL layer 763 included in the light-emitting device illustrated in FIG. 13A. Specifically, the light-emitting device illustrated in FIG. 13B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771 and light-emitting layers 772 and 773) are provided between the layer 780 and the layer 790 as illustrated in FIGS. 13C and 13D are variations of a single structure. Although FIGS. 13C and 13D each illustrate an example in which three light-emitting layers are included, the number of light-emitting layers in a light-emitting device with a single structure may be two or four or more. In addition, the light-emitting device with a single structure may include a buffer layer between two light-emitting layers.

As illustrated in FIGS. 13E and 13F, the EL layer 763 may have a structure in which a plurality of light-emitting units (light-emitting units 763a and 763b) are connected in series through a charge-generation layer 785 (also referred to as an intermediate layer). Such a structure is referred to as a tandem structure in this specification. Note that a tandem structure may be referred to as a stack structure. The EL layer 763 with a tandem structure enables a light-emitting device capable of high-luminance light emission. Furthermore, the amount of current needed for a predetermined luminance can be smaller in the tandem structure than in the single structure; thus, the tandem structure enables higher reliability.

Note that FIGS. 13D and 13F each illustrate an example in which the display device includes a layer 764 overlapping with the light-emitting device. FIG. 13D is an example in which the layer 764 overlaps with the light-emitting device illustrated in FIG. 13C and FIG. 13F illustrates an example in which the layer 764 overlaps with the light-emitting device illustrated in FIG. 13E. In FIGS. 13D and 13F, a conductive film that transmits visible light is used for the upper electrode 762 so that light is extracted from the upper electrode 762 side.

One or both of a color conversion layer and a color filter (coloring layer) can be used as the layer 764.

In FIGS. 13C and 13D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that emits blue light, blue light from the light-emitting device can be extracted as it is. In each of a subpixel that emits red light and a subpixel that emits green light, a color conversion layer is provided as the layer 764 illustrated in FIG. 13D for converting blue light from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIGS. 13C and 13D, the light-emitting layers 771, 772, and 773 may be formed using light-emitting substances that emit light of different colors. When the light-emitting layers 771, 772, and 773 emit light of complementary colors, white light emission can be obtained. The light-emitting device with a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 13D. When white light passes through a color filter, light of a desired color can be obtained.

In the case where the light-emitting device with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device with a single structure includes two light-emitting layers, for example, a light-emitting layer containing a light-emitting substance emitting blue (B) light and a light-emitting layer containing a light-emitting substance emitting yellow (Y) light are preferably included. Such a structure may be referred to as a BY single structure.

In the light-emitting device that emits white light, two or more kinds of light-emitting substances are preferably contained. To obtain white light emission, the two or more kinds of light-emitting substances can be selected so as to emit light of complementary colors. For example, when emission colors of a first light-emitting layer and a second light-emitting layer are complementary colors, the light-emitting device can emit white light as a whole. The same applies to a light-emitting device including three or more light-emitting layers.

In FIGS. 13C and 13D, the layers 780 and 790 may each have a stacked-layer structure of two or more layers as illustrated in FIG. 13B.

In FIGS. 13E and 13F, light-emitting substances that emit light of the same color, or moreover, the same light-emitting substance may be used for the light-emitting layers 771 and 772. For example, in light-emitting devices included in subpixels emitting light of different colors, a light-emitting substance that emits blue light can be used for each of the light-emitting layers 771 and 772. In the subpixel that emits blue light, blue light from the light-emitting device can be extracted as it is. In each of the subpixel that emits red light and the subpixel that emits green light, a color conversion layer is provided as the layer 764 illustrated in FIG. 13F for converting blue light from the light-emitting device into light with a longer wavelength, so that red light or green light can be extracted. As the layer 764, both a color conversion layer and a coloring layer are preferably used.

In FIGS. 13E and 13F, light-emitting substances that emit light of different colors may be used for the light-emitting layers 771 and 772. When the light-emitting layers 771 and 772 emit light of complementary colors, white light emission can be obtained. As the layer 764 illustrated in FIG. 13F, a color filter may be provided. When white light passes through a color filter, light of a desired color can be obtained.

Although FIGS. 13E and 13F each illustrate an example in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 13E and 13F each illustrate an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 13E and 13F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are interchanged and the structures of the layers 780b and 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

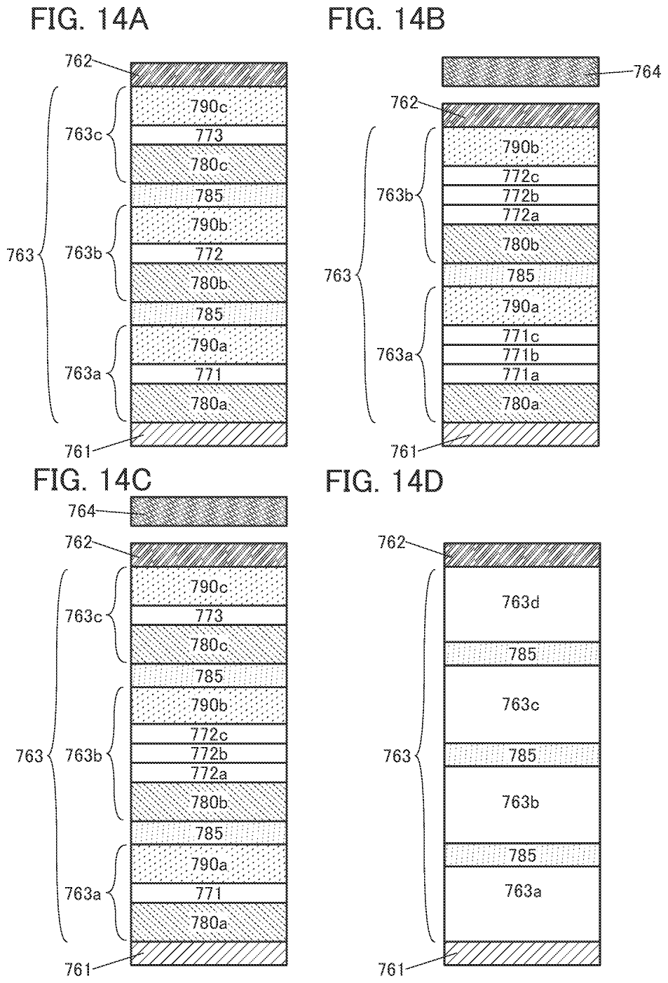

Examples of the light-emitting device with a tandem structure are structures illustrated in FIGS. 14A to 14D.

FIG. 14A illustrates a structure including three light-emitting units. In the structure illustrated in FIG. 14A, a plurality of light-emitting units (the light-emitting units 763a and 763b and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 14A, the light-emitting layers 771, 772, and 773 can each contain a light-emitting substance that emits light of the same color. Specifically, the light-emitting layers 771, 772, and 773 can each contain a blue (B) light-emitting substance (i.e., a B\B\B three-unit tandem structure). Note that “a\b” means that a light-emitting unit containing a light-emitting substance that emits light of the color “b” is provided over a light-emitting unit containing a light-emitting substance that emits light of the color “a” with a charge-generation layer therebetween.

In FIG. 14A, light-emitting substances that emit light of different colors can be used for some or all of the light-emitting layers 771, 772, and 773. Examples of a combination of emission colors for the light-emitting layers 771, 772, and 773 include blue (B) for two of them and yellow (Y) for the other; and red (R) for one of them, green (G) for another, and blue (B) for the other.

FIG. 14B illustrates a tandem light-emitting device in which light-emitting units each including a plurality of light-emitting layers are stacked. FIG. 14B illustrates a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 14B, the light-emitting unit 763a is configured to emit white (W) light by selecting light-emitting substances for the light-emitting layers 771a, 771b, and 771c so that their emission colors are complementary colors. Furthermore, the light-emitting unit 763b is configured to emit white (W) light by selecting light-emitting substances for the light-emitting layers 772a, 772b, and 772c so that their emission colors are complementary colors. That is, the structure illustrated in FIG. 14B can be referred to as a WWW two-unit tandem structure. Note that there is no particular limitation on the stacking order of the light-emitting substances having complementary emission colors. The practitioner can select the optimal stacking order as appropriate. Although not illustrated, a W\W\W three-unit tandem structure or a tandem structure with four or more units may be employed.

In the case of a light-emitting device with a tandem structure, any of the following structure may be employed, for example: a B\Y or Y\B two-unit tandem structure including a light-emitting unit that emits yellow (Y) light and a light-emitting unit that emits blue (B) light; a R·G\B or B\R·G two-unit tandem structure including a light-emitting unit that emits red (R) and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow-green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a-b” means that one light-emitting unit contains a light-emitting substance that emits light of the color “a” and a light-emitting substance that emits light of the color “b”.

As illustrated in FIG. 14C, a light-emitting unit including one light-emitting layer and a light-emitting unit including a plurality of light-emitting layers may be used in combination.

Specifically, in the structure illustrated in FIG. 14C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 14C can be, for example, a B\R·G·YG\B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

FIG. 14D illustrates a structure including four light-emitting units. In the structure illustrated in FIG. 14D, a plurality of light-emitting units (the light-emitting units 763a, 763b, and 763c and a light-emitting unit 763d) are connected in series with the charge-generation layers 785.

In FIG. 14D, all the light-emitting layers included in the light-emitting units can contain light-emitting substances that emit light of the same color. For example, all the light-emitting layers can contain a blue (B) light-emitting substance (i.e., a B\B\B\B four-unit tandem structure). Note that “alb” means that a light-emitting unit containing a light-emitting substance that emits light of the color “b” is provided over a light-emitting unit containing a light-emitting substance that emits light of the color “a” with a charge-generation layer therebetween.

Alternatively, in FIG. 14D, light-emitting substances that emit light of different colors can be used for some or all of the light-emitting layers included in the light-emitting units. The combination of emission colors of the light-emitting layers can be, for example, blue (B) for three of them and green (G) for the other; blue (B) for two of them and yellow (Y) for the others; and red (R) for one of them, green (G) for another, and blue (B) for the others. When the combination of emission colors of the light-emitting layers is blue (B) for three of them and green (G) for the other, for example, even in the case where conversion from blue light to green or red light by the color conversion layer 12G or 12R is insufficient, conversion to an objective color can be easily performed owing to the compensation of green light which has a longer wavelength than blue light. Thus, the emission colors of the subpixels 11G and 11R can be favorable. For example, the color purity can be increased.

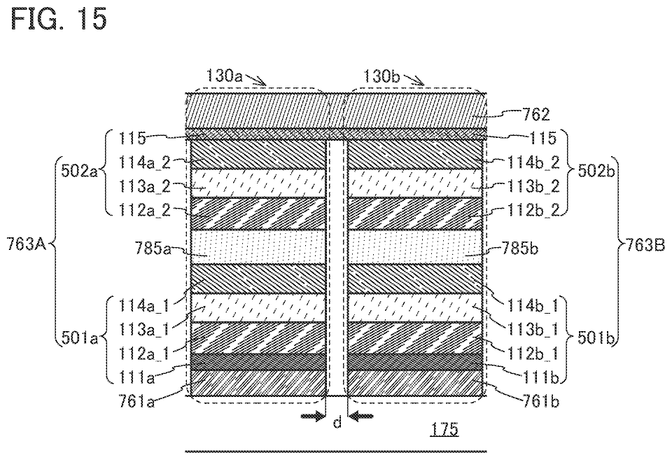

In order to describe light-emitting devices included in the light-emitting apparatus of one embodiment of the present invention, FIG. 15 illustrates two light-emitting devices (light-emitting devices 130a and 130b) which are adjacent to each other. The light-emitting devices 130a and 130b are light-emitting devices each including an EL layer processed by a lithography method.

Over the insulating layer 175, the light-emitting device 130a includes an EL layer 763A between a lower electrode 761a and the upper electrode 762. The EL layer 763A has a structure in which an EL layer 501a and an EL layer 502a are stacked with a charge-generation layer 785a therebetween. Although FIG. 15 illustrates an example in which two EL layers are stacked, three or more EL layers may be stacked. The first EL layer 501a includes a hole-injection layer 111a, a first hole-transport layer 112a_1, a first light-emitting layer 113a_1, and a first electron-transport layer 114a_1. The second EL layer 502a includes a second hole-transport layer 112a_2, a second light-emitting layer 113a_2, a second electron-transport layer 114a_2, and an electron-injection layer 115.

Over the insulating layer 175, the light-emitting device 130b includes an EL layer 763B between a lower electrode 761b and the upper electrode 762. The EL layer 763B has a structure in which an EL layer 501b and an EL layer 502b are stacked with a charge-generation layer 785b therebetween. Although two light-emitting units are stacked in the example illustrated in FIG. 15, three or more light-emitting units may be stacked. The first EL layer 501b includes a hole-injection layer 111b, a first hole-transport layer 112b_1, a first light-emitting layer 113b_1, and a first electron-transport layer 114b_1. The second EL layer 502b includes a second hole-transport layer 112b_2, a second light-emitting layer 113b_2, a second electron-transport layer 114b_2, and the electron-injection layer 115.

The electron-injection layer 115 and the upper electrode 762 are preferably a continuous layer shared by the light-emitting devices 130a and 130b. The EL layers 763A and 763B, except for the electron-injection layer 115, are processed by a lithography method after the second electron-transport layer 114a_2 is formed and after the second electron-transport layer 114b_2 is formed and thus are independent of each other. Furthermore, the end portions (contours) of the EL layers 763A and 763B except for the electron-injection layer 115 are substantially aligned in the direction perpendicular to the substrate because of being processed by a lithography method.

Since an organic compound layer is processed by a lithography method, the distance d between the lower electrode 761a and the lower electrode 761b can be smaller than that in the case of performing mask vapor deposition, and can be shortened to less than 10 μm, 8 μm or less, 5 μm or less, 3 μm or less, 2 μm or less, 1.5 μm or less, 1 μm or less, or 0.5 μm or less. Using a light exposure apparatus for LSI can further shorten the distance d to 500 nm or less, 200 nm or less, 100 nm or less, or even 50 nm or less, for example, in a process over a Si wafer.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display device includes a light-emitting device emitting infrared light, it is preferable that a conductive film transmitting visible light and infrared light be used for the electrode through which light is extracted, and a conductive film reflecting visible light and infrared light be used for the electrode through which light is not extracted.

A conductive film transmitting visible light may be used also for the electrode through which light is not extracted. In that case, the electrode is preferably provided between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device preferably has an electrode having properties of transmitting and reflecting visible light (transflective electrode), and the other preferably has an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a visible-light-transmitting property (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and contains a material having a high hole-injection property. Examples of a material having a high hole-injection property include an aromatic amine compound and a composite material containing a hole-transport material and an acceptor material (electron-accepting material).

As the hole-transport material, an aftermentioned material having a high hole-transport property usable for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material having a high hole-injection property, a material that contains a hole-transport material and the above-described oxide of a metal belonging to Group 4 to Group 8 of the periodic table (typified by molybdenum oxide) may be used, for example.

The hole-transport layer transports holes injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, materials having a high hole-transport property, such as a T-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer has a hole-transport property and contains a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and contains a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and contains a material having a high electron-injection property. As the material having a high electron-injection property, an alkali metal, an alkaline earth metal, or a compound thereof can be used. As the material having a high electron-injection property, a composite material containing an electron-transport material and a donor material (electron-donating material) can also be used.

The LUMO level of the material having a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato) lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiO_{X}), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c] phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that mPPhen2P and NBPhen have a higher glass transition point (Tg) than BPhen and thus has high heat resistance.

As described above, the charge-generation layer includes at least a charge-generation region. The charge-generation region preferably contains an acceptor material. For example, the charge-generation region preferably contains the above-described hole-transport material and acceptor material that can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, the above-described material that can be used for the electron-injection layer can be favorably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) and transferring electrons smoothly.

For the electron-relay layer, a phthalocyanine-based material such as copper (II) phthalocyanine (abbreviation: CuPc), or a metal complex having a metal-oxygen bond and an aromatic ligand is preferably used.

Note that the charge-generation region, the electron-injection buffer layer, and the electron-relay layer are difficult to distinguish clearly from one another on the basis of the cross-sectional shape or properties in some cases.

The charge-generation layer may contain a donor material instead of an acceptor material. For example, the charge-generation layer may include a layer containing the above-described electron-transport material and donor material that can be used for the electron-injection layer.

When the charge-generation layer is provided between two light-emitting units to be stacked, an increase in driving voltage can be inhibited.

Note that an organic compound layer (also referred to as a cap layer) can be provided on the surface of the upper electrode on the substrate 10 side. The use of a material with a high refractive index for the cap layer can improve the light extraction efficiency. For example, the ordinary refractive index nₒ is preferably greater than or equal to 1.9 in a blue region (e.g., 450 nm), in which case the efficiency is greatly improved. The cap layer preferably does not contain oxygen because of being provided near the color conversion layers 12R, 12G, and 12B. The cap layer is preferably formed using a material containing nitrogen, and the number of nitrogen atoms is preferably greater than the number of oxygen atoms in the composition formula of the material. The use of a material having such a composition can prevent diffusion of impurities from the cap layer into the color conversion layers 12R, 12G, and 12B.

This embodiment can be combined with any of the other embodiments as appropriate.

### Embodiment 6

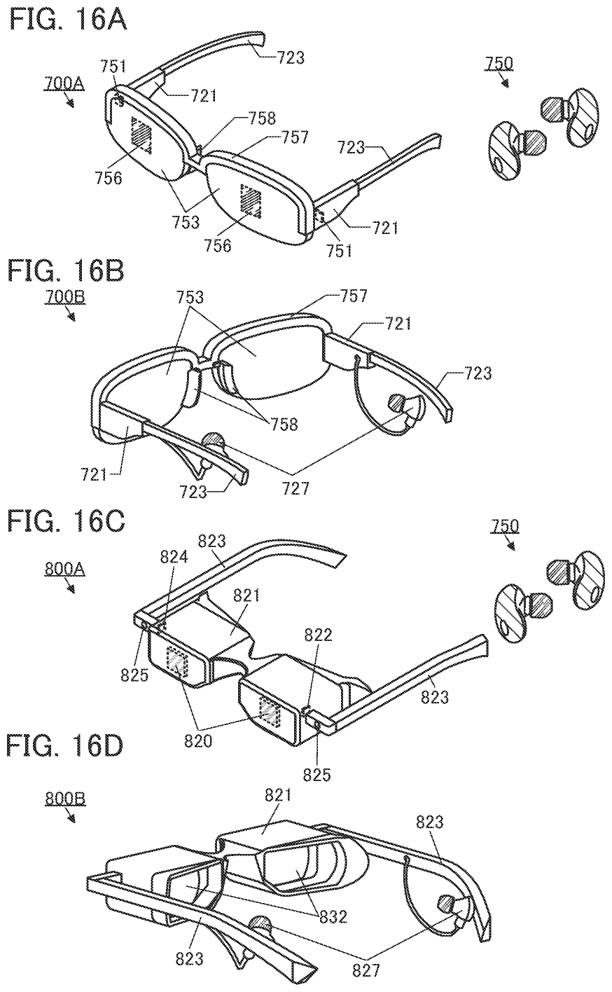

In this embodiment, electronic appliances of embodiments of the present invention will be described with reference to FIGS. 16A to 16D, FIGS. 17A to 17F, and FIGS. 18A to 18G.

Electronic appliances of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic appliance having a relatively small display portion. Examples of such an electronic appliance include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic appliance in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic appliance in this embodiment can have a variety of functions. For example, the electronic appliance in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 16A to 16D. The wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 16A and an electronic appliance 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliances are capable of performing ultrahigh-resolution display.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliances 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic appliance 800A illustrated in FIG. 16C and an electronic appliance 800B illustrated in FIG. 16D each include a pair of display portions 820, a housing 821, a communication portion 822, a pair of wearing portions 823, a control portion 824, a pair of image capturing portions 825, and a pair of lenses 832. The display device of one embodiment of the present invention can be used in the display portions 820. Thus, the electronic appliances are capable of performing ultrahigh-resolution display. Such electronic appliances provide a high sense of immersion to the user.

The display portions 820 are provided inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or the electronic appliance 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or the electronic appliance 800B can be mounted on the user's head with the wearing portions 823. FIG. 16C and the like illustrate examples where the wearing portion 823 has a shape like a temple (also referred to as a joint or the like) of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal (also referred to as an input portion). To the input terminal, a cable for supplying a video signal from a video output device or the like, electric power for charging the battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 16A has a function of transmitting information to the earphones 750 with the wireless communication function. As another example, the electronic appliance 800A in FIG. 16C has a function of transmitting information to the earphones 750 with the wireless communication function.

The electronic appliance may include an earphone portion. The electronic appliance 700B in FIG. 16B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic appliance 800B in FIG. 16D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

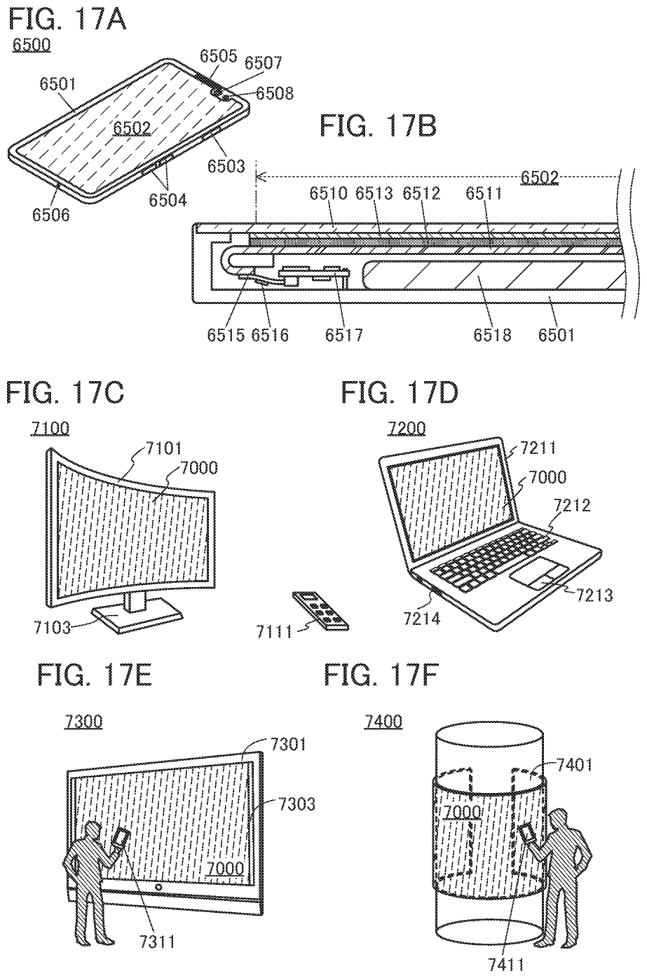

An electronic appliance 6500 illustrated in FIG. 17A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic appliance can be achieved. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be achieved.

FIG. 17C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 17C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 17D illustrates an example of a laptop personal computer. The laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 17E and 17F illustrate examples of digital signage.

Digital signage 7300 illustrated in FIG. 17E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 17F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 17E and 17F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIGS. 17E and 17F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

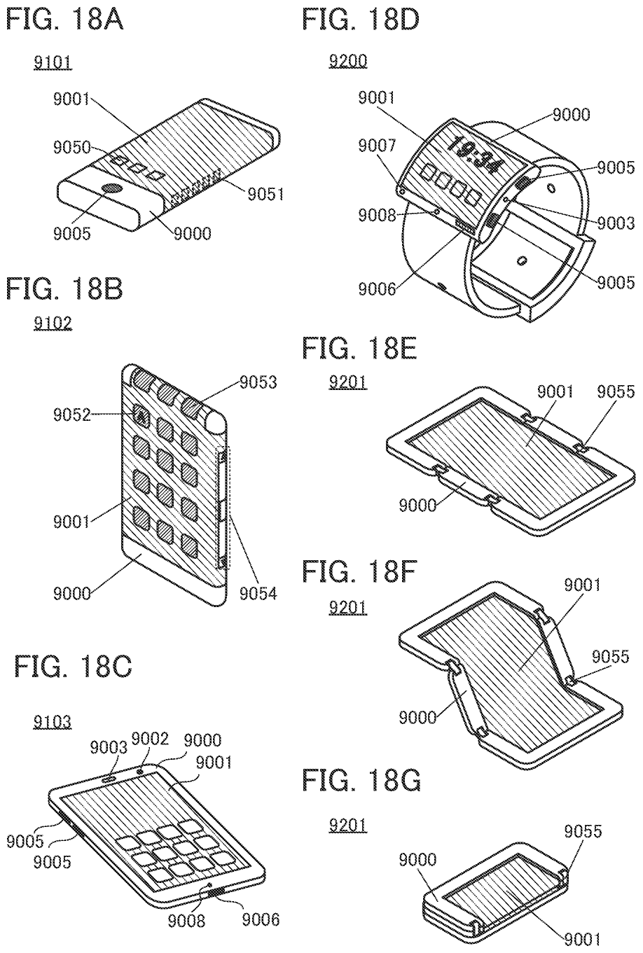

Electronic appliances illustrated in FIGS. 18A to 18G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The electronic appliances illustrated in FIGS. 18A to 18G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of capturing a still image or a moving image and storing the captured image in a storage medium (an external storage medium or a storage medium incorporated in the camera), a function of displaying the captured image on the display portion, and the like.

The electronic appliances in FIGS. 18A to 18G will be described in detail below.

FIG. 18A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 18A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 18C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 18E to 18G are perspective views of a foldable portable information terminal 9201. FIG. 18E is a perspective view illustrating the portable information terminal 9201 that is opened. FIG. 18G is a perspective view illustrating the portable information terminal 9201 that is folded. FIG. 18F is a perspective view illustrating the portable information terminal 9201 that is shifted from one of the states in FIGS. 18E and 18G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

This application is based on Japanese Patent Application Serial No. 2023-070064 filed with Japan Patent Office on Apr. 21, 2023, the entire contents of which are hereby incorporated by reference.

What is claimed is:

1. A display device comprising:
a substrate;
an insulating layer over the substrate;
a color conversion layer;
a first inorganic film; and
a second inorganic film,
wherein the insulating layer comprises an opening,
wherein the color conversion layer is in the opening,
wherein the first inorganic film comprises a first portion between the insulating layer and the color conversion layer in the opening and a second portion between the substrate and the color conversion layer in the opening, and
wherein the second inorganic film is over the color conversion layer.

2. A display device comprising:
a substrate;
an insulating layer over the substrate;
a color conversion layer;
a first inorganic film; and
a second inorganic film,
wherein the insulating layer comprises an opening,
wherein the color conversion layer is in the opening,
wherein the first inorganic film comprises a first portion between the insulating layer and the color conversion layer in the opening, a second portion between the substrate and the color conversion layer in the opening, and a third portion over the insulating layer, and
wherein the second inorganic film is over the color conversion layer and the third portion.

3. The display device according to claim 2,
wherein the third portion is in contact with the second inorganic film.

4. A display device comprising:
a substrate;
an insulating layer over the substrate;
a color conversion layer;
a first inorganic film;
a second inorganic film; and
a third inorganic film,
wherein the insulating layer comprises an opening,
wherein the color conversion layer is in the opening,
wherein the first inorganic film comprises a first portion between the insulating layer and the color conversion layer in the opening, a second portion between the substrate and the color conversion layer in the opening, and a third portion over the insulating layer,
wherein the second inorganic film is over the color conversion layer and the third portion, and
wherein the third inorganic film comprises a portion between the substrate and the insulating layer and a portion between the substrate and the first inorganic film.

5. The display device according to claim 4,
wherein the first inorganic film comprises a fourth portion in contact with the second inorganic film and the third inorganic film.

6. The display device according to claim 1,
wherein a height from a top surface of the substrate to a top surface of the insulating layer is higher than a height from the top surface of the substrate to a top surface of the color conversion layer.

7. The display device according to claim 1, further comprising a coloring layer,
wherein the coloring layer comprises a portion between the substrate and the insulating layer and a portion between the substrate and the first inorganic film.

8. The display device according to claim 1, further comprising a light-emitting device,
wherein the light-emitting device overlaps with the color conversion layer.

9. An electronic appliance comprising the display device according to claim 1, and at least one of a sensing portion, an input portion, and a communication portion.

10. The display device according to claim 2,
wherein a height from a top surface of the substrate to a top surface of the insulating layer is higher than a height from the top surface of the substrate to a top surface of the color conversion layer.

11. The display device according to claim 2, further comprising a coloring layer,
wherein the coloring layer comprises a portion between the substrate and the insulating layer and a portion between the substrate and the first inorganic film.

12. The display device according to claim 2, further comprising a light-emitting device,
wherein the light-emitting device overlaps with the color conversion layer.

13. An electronic appliance comprising the display device according to claim 2, and at least one of a sensing portion, an input portion, and a communication portion.

14. The display device according to claim 4,
wherein a height from a top surface of the substrate to a top surface of the insulating layer is higher than a height from the top surface of the substrate to a top surface of the color conversion layer.

15. The display device according to claim 4, further comprising a coloring layer,
wherein the coloring layer comprises a portion between the substrate and the insulating layer and a portion between the substrate and the first inorganic film.

16. The display device according to claim 4, further comprising a light-emitting device,
wherein the light-emitting device overlaps with the color conversion layer.

17. An electronic appliance comprising the display device according to claim 4, and at least one of a sensing portion, an input portion, and a communication portion.
